(19) United States
(12) Patent Application Publication
(10) Pub. No.: US 2026/0271477 A1
(43) Pub. Date: Sep. 10, 2026

(54) PHOTOELECTRIC CONVERSION ELEMENT, PHOTOELECTRIC CONVERSION MODULE, ELECTRONIC DEVICE, POWER SUPPLY MODULE, AND LIQUID COMPOSITION

(71) Applicants: Satoshi YAMAMOTO, Shizuoka (JP); Yuuji TANAKA, Shizuoka (JP); Nozomu TAMOTO, Shizuoka (JP)

(72) Inventors: Satoshi YAMAMOTO, Shizuoka (JP); Yuuji TANAKA, Shizuoka (JP); Nozomu TAMOTO, Shizuoka (JP)

(21) Appl. No.: 19/166,044

(22) PCT Filed: Mar. 18, 2024
(86) PCT No.: PCT/JP2024/010623

§ 371 Date: Sep. 17, 2025

(30) Foreign Application Priority Data
Mar. 20, 2023 (JP) 2023-044628

(51) Int. Cl. H10K 30/50; H10K 30/30; H10K 30/40; H10K 85/10

(52) U.S. Cl. CPC H10K 30/50; H10K 30/30; H10K 30/40; H10K 85/113; H10K 85/114

(57) ABSTRACT

A photoelectric conversion element includes a hole-transporting layer. The hole-transporting layer contains a polymer compound having a constituent unit represented by formula (1) below, and a compound represented by formula (2) below: in formula (1), Ar¹, Ar², and Ar³ each independently represent a divalent group of a substituted or unsubstituted, monocyclic, non-condensed polycyclic, or condensed polycyclic aromatic hydrocarbon group, and R¹ represents hydrogen, an alkyl group, or an aryl group; in formula (2), M represents boron, aluminum, phosphorus, or antimony, and R₂, R₃, and R₄ represent hydrogen, a halogen, an alkyl group, an alkoxy group, an aryl group, a heteroaryl group, an ether bond-containing group, or an ester bond-containing group.

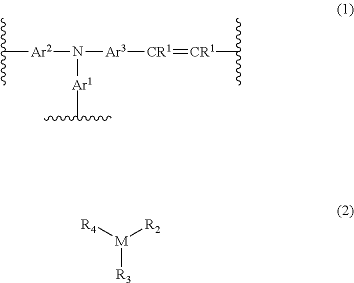

### TECHNICAL FIELD

The present disclosure relates to photoelectric conversion elements, photoelectric conversion modules, electronic devices, power supply modules, and liquid compositions.

### BACKGROUND ART

In recent years, various applications of solar cells using a photoelectric conversion element have been expected not only in terms of alternatives to fossil fuels and measures against global warming but also as stand-alone power supplies that do not require replacement of a cell, power source wiring, or the like. Moreover, the solar cells as the stand-alone power supplies attract keen attention as one of the energy harvesting techniques required in internet of things (IoT) devices or artificial satellites.

Examples of the solar cells include organic solar cells such as dye-sensitized solar cells, organic thin film solar cells, and perovskite solar cells (see, for example, PTL 1) in addition to inorganic solar cells using silicon that have been widely used.

### CITATION LIST

### Patent Literature

PTL 1: Japanese Unexamined Patent Application Publication No. 2020-053616

### SUMMARY OF INVENTION

### Technical Problem

It is an object of the present disclosure to provide a photoelectric conversion element that has excellent initial output, and even after long-term exposure to light, can maintain excellent power generation efficiency.

### Solution to Problem

According to one aspect of the present disclosure, a photoelectric conversion element includes a hole-transporting layer. The hole-transporting layer contains: a polymer compound having a constituent unit represented by formula (1) below; and a compound represented by formula (2) below.

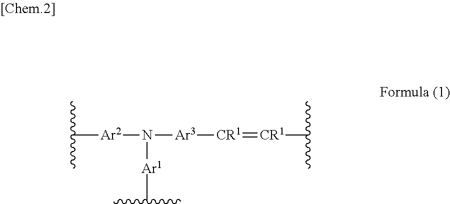

In formula (1), Ar¹, Ar², and Ar³ each independently represent a divalent group of a substituted or unsubstituted, monocyclic, non-condensed polycyclic, or condensed polycyclic aromatic hydrocarbon group, and R¹ represents hydrogen, an alkyl group, or an aryl group.

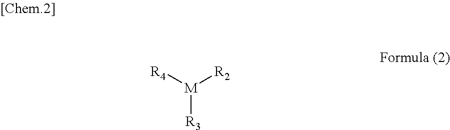

In formula (2), M represents boron, aluminum, phosphorus, or antimony, and R₂, R₃, and R₄ represent hydrogen, a halogen, an alkyl group, an alkoxy group, an aryl group, a heteroaryl group, an ether bond-containing group, or an ester bond-containing group.

### Advantageous Effects of Invention

According to the present disclosure, it is possible to provide a photoelectric conversion element that has excellent initial output, and even after long-term exposure to light, can maintain excellent power generation efficiency.

### BRIEF DESCRIPTION OF DRAWINGS

FIG. 1A is a cross-sectional view illustrating one example of a solar battery cell as one embodiment of a photoelectric conversion element.

FIG. 1B is a cross-sectional view illustrating one example of one embodiment of a solar battery module.

FIG. 1C is a cross-sectional view illustrating one example of another embodiment of the solar battery module.

FIG. 1D is a cross-sectional view illustrating one example of still another embodiment of the solar battery module.

FIG. 1E is a cross-sectional view illustrating one example of yet another embodiment of the solar battery module.

FIG. 1F is a cross-sectional view illustrating one example of even another embodiment of the solar battery module.

FIG. 2 is a block diagram of a mouse for a personal computer as one example of an electronic device of the present disclosure.

FIG. 3 is a schematic external view illustrating one example of the mouse illustrated in FIG. 2.

FIG. 4 is a block diagram of a keyboard for a personal computer as one example of the electronic device of the present disclosure.

FIG. 5 is a schematic external view illustrating one example of the keyboard illustrated in FIG. 4.

FIG. 6 is a schematic external view illustrating another example of the keyboard illustrated in FIG. 4.

FIG. 7 is a block diagram of a sensor as one example of the electronic device of the present disclosure.

FIG. 8 is a block diagram of a turntable as one example of the electronic device of the present disclosure.

FIG. 9 is a block diagram illustrating one example of the electronic device of the present disclosure.

FIG. 10 is a block diagram illustrating one example in which a power supply integrated circuit (IC) is further included in the electronic device illustrated in FIG. 9.

FIG. 11 is a block diagram illustrating one example in which an electricity storage device is further included in the electronic device illustrated in FIG. 10.

FIG. 12 is a block diagram illustrating one example of a power supply module of the present disclosure.

FIG. 13 is a block diagram illustrating one example in which an electricity storage device is further included in the power supply module illustrated in FIG. 12.

### DESCRIPTION OF EMBODIMENTS

### (Photoelectric Conversion Element)

The photoelectric conversion element of the present disclosure includes the hole-transporting layer, preferably includes a first electrode, a photoelectric conversion layer, and a second electrode, and if necessary, further includes other layers.

The hole-transporting layer contains: a polymer compound having a constituent unit represented by formula (1) below; and a compound represented by formula (2) below.

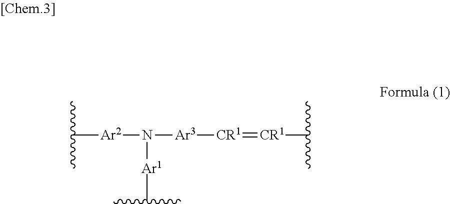

In formula (1), Ar¹, Ar², and Ar³ each independently represent a divalent group of a substituted or unsubstituted, monocyclic, non-condensed polycyclic, or condensed polycyclic aromatic hydrocarbon group, and R¹ represents hydrogen, an alkyl group, or an aryl group.

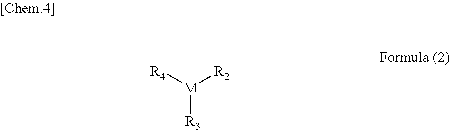

In formula (2), M represents boron, aluminum, phosphorus, or antimony, and R₂, R₃, and R₄ represent hydrogen, a halogen, an alkyl group, an alkoxy group, an aryl group, a heteroaryl group, an ether bond-containing group, or an ester bond-containing group.

The present inventors conducted intensive studies, and have found that when the hole-transporting layer contains the polymer compound having the constituent unit represented by formula (1) and the compound represented by formula (2), it is possible to obtain a photoelectric conversion element having excellent initial output. In addition, even after long-term exposure to light of a high illuminance, the photoelectric conversion element can maintain power generation efficiency.

The photoelectric conversion element means an element that can convert light energy into electric energy or can convert electric energy into light energy, and is applied to, for example, solar cells and photodiodes.

The photoelectric conversion element of the present disclosure includes the hole-transporting layer, and if necessary, further includes a first substrate, a first electrode, a photoelectric conversion layer, an electron-transporting layer, a second electrode, a second substrate, and other members.

### First Embodiment

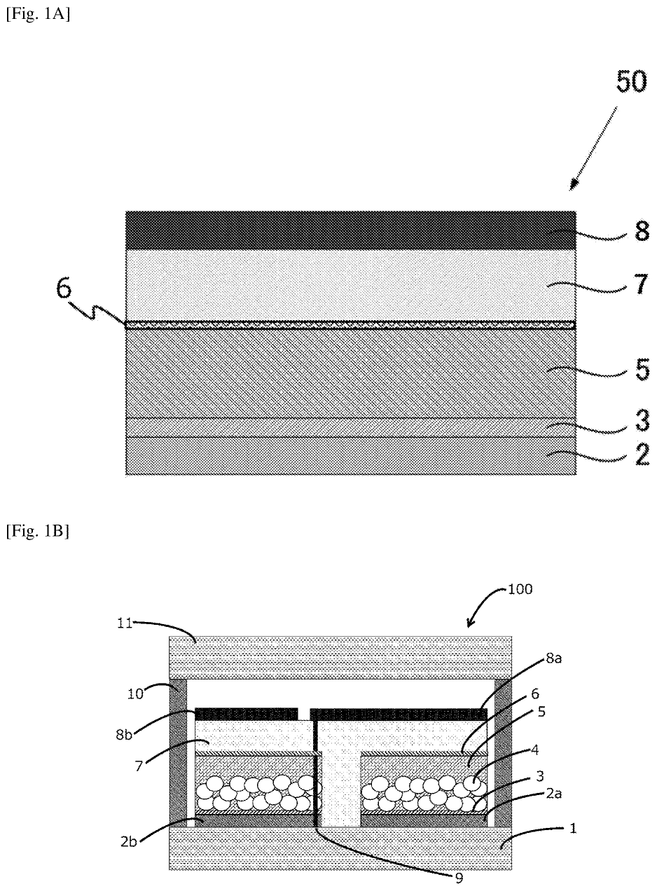

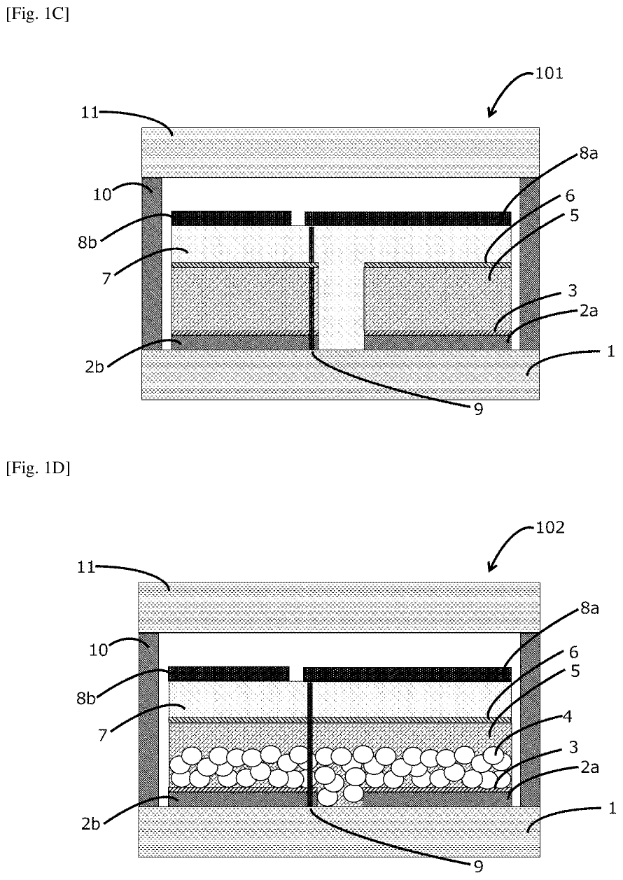

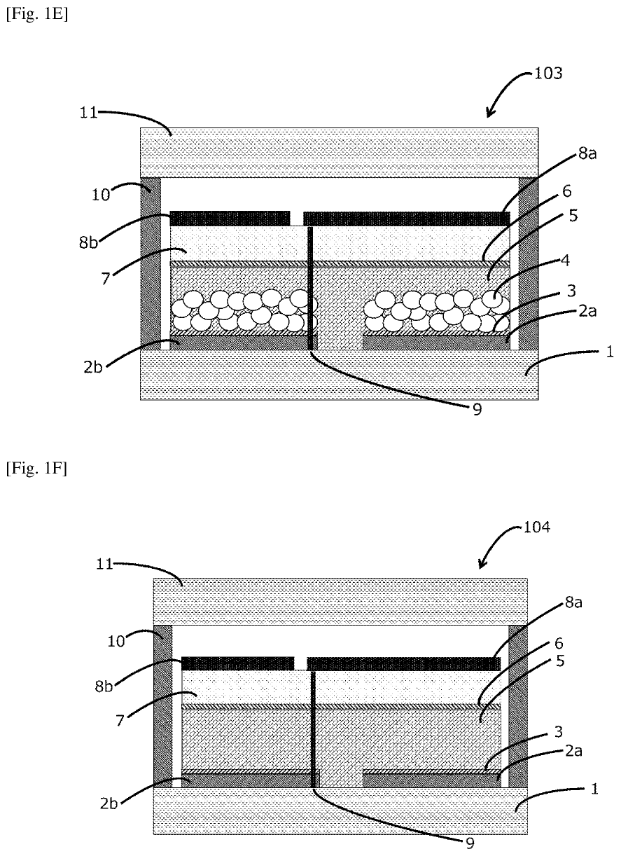

FIG. 1A is a cross-sectional view illustrating one example of the solar battery cell as one embodiment of the photoelectric conversion element.

A solar battery cell 50 as illustrated in FIG. 1A includes a first electrode 2, an electron-transporting layer 3, a perovskite layer 5 serving as a photoelectric conversion layer, a hole-transporting layer 7, and a second electrode 8.

The first electrode 2 is in contact with the electron-transporting layer 3. The electron-transporting layer 3 is in contact with the perovskite layer 5. The electron-transporting layer 3 may be a two-layered structure of a dense electron-transporting layer (hereinafter may be referred to as “dense layer”) and a porous electron-transporting layer (hereinafter may be referred to as “porous layer”). The perovskite layer 5 is above the hole-transporting layer 7. A film (layer) 6 containing a compound represented by formula (6) (hereinafter may be referred to as “formula (6) compound”) is provided between the perovskite layer 5 and the hole-transporting layer 7.

The hole-transporting layer 7 is in contact with the second electrode 8.

### <Hole-Transporting Layer>

The hole-transporting layer means a layer that transports holes generated in the photoelectric conversion layer to the second electrode that will be described below. Therefore, preferably, the hole-transporting layer is disposed next to the photoelectric conversion layer via a salt or disposed directly next to the photoelectric conversion layer.

The hole-transporting layer contains the polymer compound having the constituent unit represented by formula (1) and the compound represented by formula (2), and if necessary further contains other components.

The compound represented by formula (2) functions as an oxidant in the hole-transporting layer.

When the hole-transporting layer contains a mixture of the polymer compound having the constituent unit represented by formula (1) and the compound represented by formula (2), a resulting photoelectric conversion element has excellent initial output, and even after long-term exposure to light of a high illuminance, can maintain excellent power generation efficiency.

### <<Polymer Compound Having the Constituent Unit Represented by Formula (1)>>

The polymer compound having the constituent unit represented by formula (1) is a polymer compound having formula (1) as a constituent unit thereof.

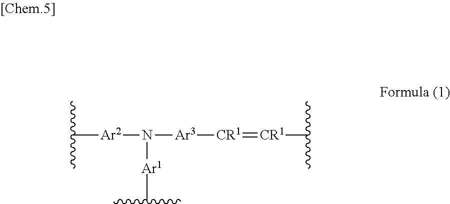

In formula (1), Ar¹, Ar², and Ar³ each independently represent a divalent group of a substituted or unsubstituted, monocyclic, non-condensed polycyclic, or condensed polycyclic aromatic hydrocarbon group, and R¹ represents hydrogen, an alkyl group, or an aryl group.

Having formula (1) as a constituent unit thereof may be having a repeated structure of formula (1) or may be having a repeated structure of a structure containing formula (1).

Ar¹, Ar², and Ar³ in formula (1) each independently represent a divalent group of a substituted (hereinafter may be referred to as “substituent-containing”) or unsubstituted, monocyclic, non-condensed polycyclic, or condensed polycyclic aromatic hydrocarbon group.

No particular limitation is imposed on the monocyclic, non-condensed polycyclic, or condensed polycyclic aromatic hydrocarbon group, which may be appropriately selected in accordance with the intended purpose. Examples thereof include an aryl group, an arylene group, a divalent heterocyclic group, and the like.

No particular limitation is imposed on the aryl group, which may be appropriately selected in accordance with the intended purpose. Examples thereof include a phenyl group, a 1-naphthyl group, a 9-anthracenyl group, and the like.

No particular limitation is imposed on the arylene group, which may be appropriately selected in accordance with the intended purpose. Examples thereof include 1,4-phenylene, 1,1′-biphenylene, 9,9′-di-n-hexylfluorene, and the like.

No particular limitation is imposed on the divalent heterocyclic group, which may be appropriately selected in accordance with the intended purpose. Examples thereof include 2,5-thiophene and the like.

No particular limitation is imposed on the substituent, which may be appropriately selected in accordance with the intended purpose. Examples thereof include an alkyl group, an alkoxy group, an aryl group, and the like.

R¹ in formula (1) represents hydrogen, an alkyl group, or an aryl group.

The polymer compound having the constituent unit represented by formula (1) is preferably a compound represented by formula (3). Inclusion of the compound represented by formula (3) leads to excellent hole transportability.

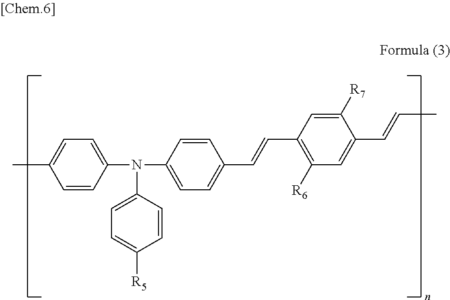

In formula (3), R₅ represents hydrogen, an aryl group, a methyl group, or a methoxy group, R₆ and R₇ represent hydrogen or an alkoxy group, and n is an integer of 2 or more.

No particular limitation is imposed on the polymer compound having the constituent unit represented by formula (1), which may be appropriately selected in accordance with the intended purpose. Specific examples thereof include the following (A-1) to (A-28), and the like.

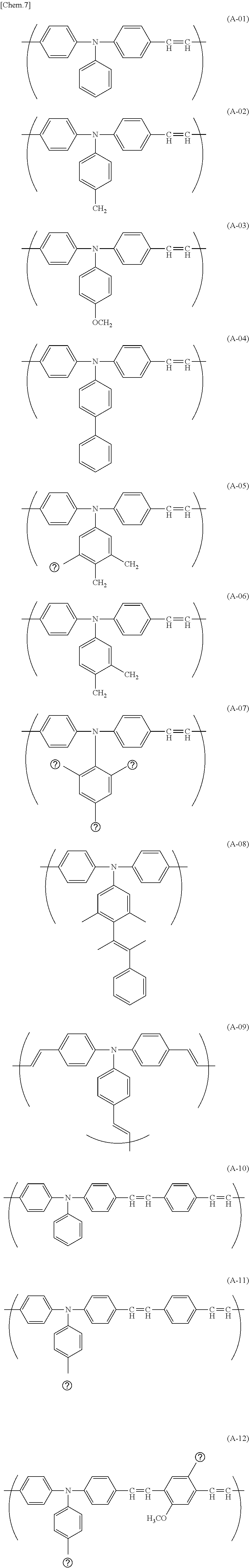

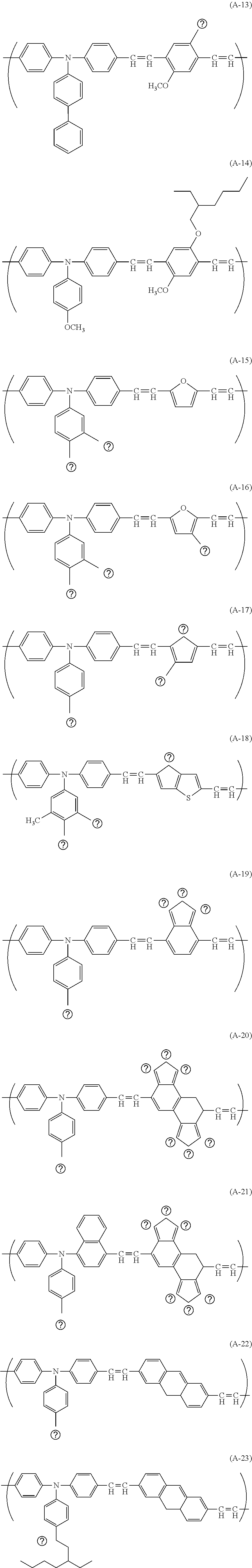

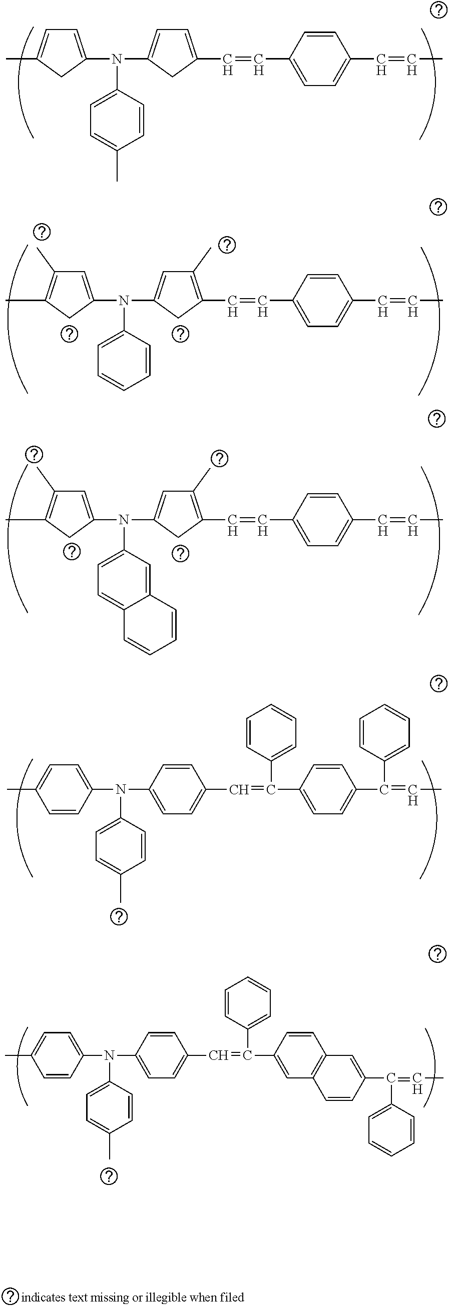

No particular limitation is imposed on a weight average molecular weight of the polymer compound having the constituent unit represented by formula (1), which may be appropriately selected in accordance with the intended purpose. However, the weight average molecular weight thereof is preferably 2,000 or higher and 150,000 or lower.

The weight average molecular weight can be measured through gel permeation chromatography (GPC).

No particular limitation is imposed on an amount of the polymer compound having the constituent unit represented by formula (1), which may be appropriately selected in accordance with the intended purpose. However, the amount thereof is preferably 30% by mass or more and 95.5% by mass or less with respect to the hole-transporting layer.

### <<Compound Represented by Formula (2)>>

The compound represented by formula (2) is a compound represented by the following formula (2).

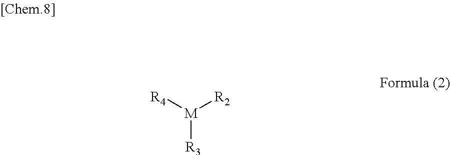

In formula (2), M represents boron, aluminum, phosphorus, or antimony, and R₂, R₃, and R₄ represent hydrogen, a halogen, an alkyl group, an alkoxy group, an aryl group, a heteroaryl group, an ether bond-containing group, or an ester bond-containing group.

R₂, R₃, and R₄ in formula (2) each independently represent hydrogen, a halogen, an alkyl group, an alkoxy group, an aryl group, a heteroaryl group, an ether bond-containing group, or an ester bond-containing group. Of these, an aryl group is preferable.

No particular limitation is imposed on the halogen, which may be appropriately selected in accordance with the intended purpose. Examples thereof include fluorine, chlorine, bromine, iodine, and the like.

No particular limitation is imposed on the alkyl group, which may be appropriately selected in accordance with the intended purpose. Examples thereof include alkyl groups having from 1 through 6 carbon atoms, such as a methyl group, an ethyl group, and the like. The alkyl group may be substituted with the halogen.

No particular limitation is imposed on the alkoxy group, which may be appropriately selected in accordance with the intended purpose. Examples thereof include alkoxy groups having from 1 through 6 carbon atoms, and the like.

No particular limitation is imposed on the aryl group, which may be appropriately selected in accordance with the intended purpose. Examples thereof include aryl groups that are substituted with a phenyl group, a 2-naphthyl group, fluorine, or the like. Of these, the aryl group substituted with fluorine is preferable. Moreover, at least two selected from the group consisting of R₂, R₃, and R₄ are preferably the aryl group substituted with fluorine.

The alkyl group or the aryl group may have a substituent.

The compound represented by formula (2) is preferably a compound represented by the following formula (4). Inclusion of the compound represented by formula (4) leads to excellent hole transportability.

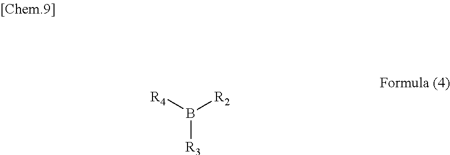

In formula (4), R₂, R₃, and R₄ represent hydrogen, a halogen, an alkyl group, an alkoxy group, an aryl group, a heteroaryl group, an ether bond-containing group, or an ester bond-containing group.

Specific examples of the compound represented by formula (2) include the following (B-1) to (B-17), and the like. Of these, (B-1) and (B-15) are preferable in view that these are Lewis acids.

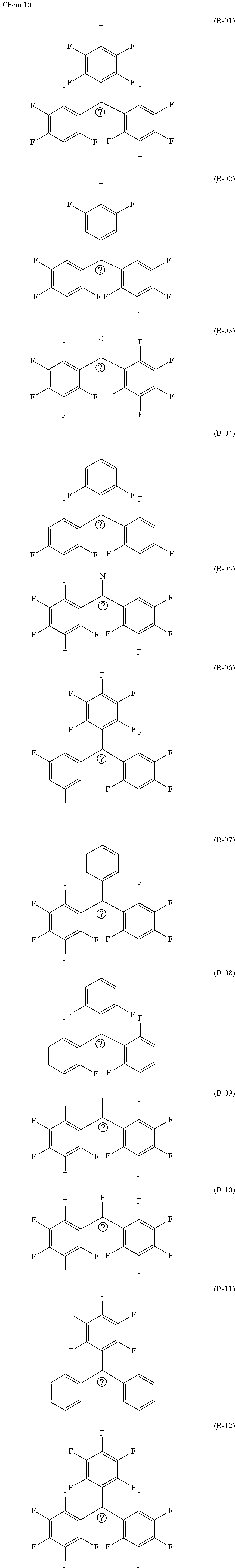

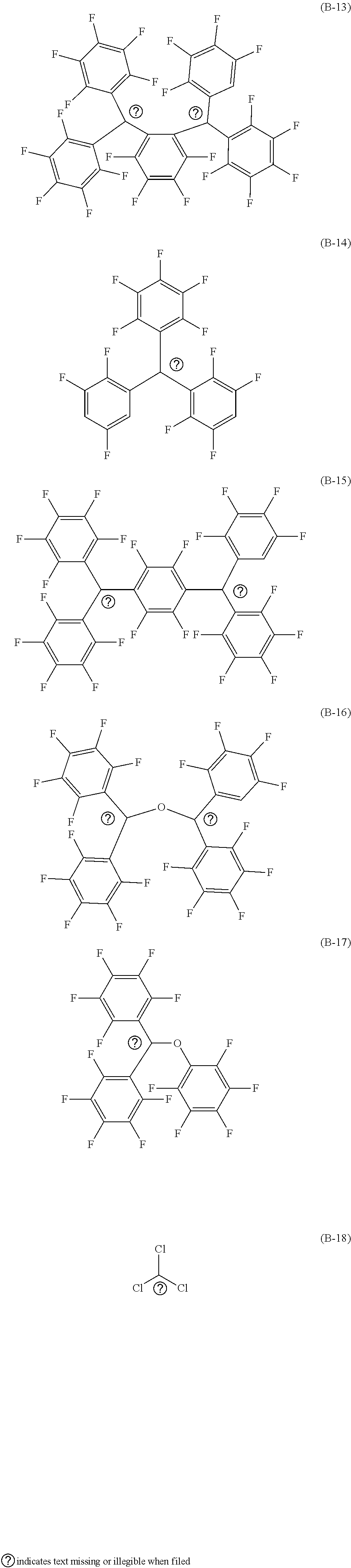

No particular limitation is imposed on a weight average molecular weight of the compound represented by formula (2), which may be appropriately selected in accordance with the intended purpose. However, the weight average molecular weight thereof is preferably 150 or higher and 1,600 or lower.

The weight average molecular weight can be measured through gel permeation chromatography (GPC).

No particular limitation is imposed on an amount of the compound represented by formula (2), which may be appropriately selected in accordance with the intended purpose. However, the amount thereof is preferably 0.1% by mass or more and 30% by mass or less with respect to the hole-transporting layer.

No particular limitation is imposed on a mass ratio (A/B) where A denotes a content of the polymer compound having the constituent unit represented by formula (1) and B denotes a content of the compound represented by formula (2). The mass ratio (A/B) may be appropriately selected in accordance with the intended purpose, but is preferably 1 or higher and 100 or lower and more preferably 10 or higher and 100 or lower. When the mass ratio (A/B) is 1 or higher, sufficient hole transportability can be obtained. When the mass ratio (A/B) is 100 or lower, excellent initial output and light resistance can be obtained.

The hole-transporting layer further includes other solid hole-transporting materials and the like, and if necessary, still further includes other materials.

No particular limitation is imposed on the other solid hole-transporting materials (hereinafter may be referred to simply as “hole-transporting material”), which may be appropriately selected in accordance with the intended purpose as long as the hole-transporting material is a material having an ability to transport holes. The hole-transporting layer preferably includes an organic compound.

### <<Other Components>>

No particular limitation is imposed on the other components contained in the hole-transporting layer, which may be appropriately selected in accordance with the intended purpose. Examples thereof include polymer materials other than the polymer compound having the constituent unit represented by formula (1), additives, cation species-free oxidants (hereinafter may be referred to as “neutral oxidant”), and the like.

No particular limitation is imposed on the polymer materials other than the polymer compound having the constituent unit represented by formula (1), which may be appropriately selected in accordance with the intended purpose. Examples thereof include polythiophene compounds, polyphenylene vinylene compounds, polyfluorene compounds, polyphenylene compounds, polyarylamine compounds, and poly-thiadiazole compounds.

No particular limitation is imposed on the additives, which may be appropriately selected in accordance with the intended purpose. Examples thereof include: iodine; metal iodides, such as lithium iodide, sodium iodide, potassium iodide, cesium iodide, calcium iodide, copper iodide, iron iodide, silver iodide, and the like; quaternary ammonium salts, such as tetraalkylammonium iodide, pyridinium iodide, and the like; metal bromides, such as lithium bromide, sodium bromide, potassium bromide, cesium bromide, calcium bromide, and the like; bromine salts of quaternary ammonium compounds, such as tetraalkylammonium bromide, pyridinium bromide, and the like; metal chlorides, such as copper chloride, silver chloride, and the like; metal acetates, such as copper acetate, silver acetate, palladium acetate, and the like; metal sulfates, such as copper sulfate, zinc sulfate, and the like; metal complexes, such as ferrocyanate-ferricyanate, ferrocene-ferricinium ion, and the like; sulfur compounds, such as sodium polysulfide, alkylthiol-alkyl disulfide, and the like; viologen dyes; hydroquinones; and basic compounds, such as pyridine, 4-t-butylpyridine, benzimidazole, and the like.

No particular limitation is imposed on the neutral oxidant, which may be appropriately selected in accordance with the intended purpose. Note that not the entirety of the hole-transporting material needs to be oxidized by the oxidant, and it is effective that the hole-transporting material is partially oxidized by the oxidant. The oxidant may or may not be removed from the reaction system after completion of the reaction.

No particular limitation is imposed on an average thickness of the hole-transporting layer, which may be appropriately selected in accordance with the intended purpose. However, the average thickness thereof is preferably 0.01 micrometers or more and 20 micrometers or less, more preferably 0.1 micrometers or more and 10 micrometers or less, and further preferably 0.2 micrometers or more and 2 micrometers or less, on the photoelectric conversion layer.

The hole-transporting layer can be formed by directly coating a liquid composition of the present disclosure onto the photoelectric conversion layer.

### (Liquid Composition)

The liquid composition of the present disclosure is a liquid composition for forming the hole-transporting layer in the present disclosure (hereinafter may be referred to as “hole-transporting layer-forming liquid composition” or “liquid composition for forming the hole-transporting layer”).

The liquid composition contains: the same compounds as in the hole-transporting layer of the photoelectric conversion element, i.e., the polymer compound having the constituent unit represented by formula (1) and the compound represented by formula (2); and if necessary, further contains other components such as organic solvents and the like.

When the liquid composition (hereinafter may be referred to as “ink”) contains the polymer compound having the constituent unit represented by formula (1) and the compound represented by formula (2), gelation of the hole-transporting layer-forming liquid composition is suppressed even after a long period of time has passed, e.g., even after 6 hours from preparation of the liquid composition. This leads to a lesser extent of time-related restriction upon formation of the hole-transporting layer. Note that the gelation is considered to occur when a cation species-containing oxidant is used and the cation species interacts with an unsaturated bond contained in the constituent unit represented by formula (1). The compound represented by formula (2) has a neutral structure and is free of a cation species, and thus the gelation is suppressed.

No particular limitation is imposed on the content of the polymer compound having the constituent unit represented by formula (1) in the liquid composition, which may be appropriately selected in accordance with the intended purpose. However, the content thereof is preferably 0.01% by mass or more and 30% by mass or less with respect to the liquid composition.

No particular limitation is imposed on the content of the compound represented by formula (2) in the liquid composition, which may be appropriately selected in accordance with the intended purpose. However, the content thereof is preferably 0.001% by mass or more and 10% by mass or less with respect to the liquid composition.

The other components may be organic solvents, and components similar to the components contained in the hole-transporting layer of the photoelectric conversion element.

No particular limitation is imposed on the organic solvents, which may be appropriately selected in accordance with the intended purpose. Examples thereof include ketone solvents, ester solvents, ether solvents, amide solvents, halogenated hydrocarbon solvents, hydrocarbon solvents, and the like.

Examples of the ketone solvents include acetone, methyl ethyl ketone, methyl isobutyl ketone, and the like.

Examples of the ester solvents include ethyl formate, ethyl acetate, n-butyl acetate, and the like.

Examples of the ether solvents include diisopropyl ether, dimethoxy ethane, tetrahydrofuran, dioxolane, dioxane, and the like.

Examples of the amide solvents include N,N-dimethylformamide, N,N-dimethylacetamide, N-methyl-2-pyrrolidone, and the like.

Examples of the halogenated hydrocarbon solvents include dichloromethane, chloroform, bromoform, methyl iodide, dichloroethane, trichloroethane, trichloroethylene, chlorobenzene, o-dichlorobenzene, fluorobenzene, bromobenzene, iodobenzene, 1-chloronaphthalene, and the like.

Examples of the hydrocarbon solvents include n-pentane, n-hexane, n-octane, 1,5-hexadiene, cyclohexane, methylcyclohexane, cyclohexadiene, benzene, toluene, oxylene, m-xylene, p-xylene, ethylbenzene, cumene, and the like.

These may be used alone or in combination.

No particular limitation is imposed on the content of the organic solvent, which may be appropriately selected in accordance with the intended purpose. However, the content thereof is preferably 60% by mass or more and 99% by mass or less with respect to the liquid composition.

No particular limitation is imposed on a method for producing the hole-transporting layer, which may be appropriately selected in accordance with the intended purpose. Examples thereof include: a method in which a thin film is formed in vacuum, such as vacuum vapor deposition; and a wet film formation method. Of these, in terms of production cost and the like, a wet film formation method is especially preferable, and a method of coating the hole-transporting layer on the photoelectric conversion layer is more preferable.

No particular limitation is imposed on the wet film formation method, which may be appropriately selected in accordance with the intended purpose. Examples thereof include the dip method, the spray method, the wire bar method, the spin coating method, the roller coating method, the blade coating method, the gravure coating method, and the like. As a wet printing method, a method such as relief printing, offset printing, gravure printing, intaglio printing, rubber plate printing, screen printing, or the like may be used.

After the hole-transporting material is stacked on the photoelectric conversion layer, a press processing step may be performed. By performing the press processing, the hole-transporting material is more closely adhered to the photoelectric conversion layer. This may improve the power generation efficiency.

No particular limitation is imposed on a method of the press processing, which may be appropriately selected in accordance with the intended purpose. Examples thereof include: the press molding method using a plate, which is represented by the infrared spectroscopy (IR) tablet molding device; and the roll press method using, for example, a roller; and the like.

A pressure at which the press processing is performed is preferably 10 kgf/cm² or more and more preferably 30 kgf/cm² or more.

No particular limitation is imposed on the time of the press processing, which may be appropriately selected in accordance with the intended purpose. The time thereof is preferably 1 hour or less. Moreover, heat may be applied at the time of the press processing.

At the time of the press processing, a release agent may be disposed between a pressing machine and the electrode.

No particular limitation is imposed on the release agent, which may be appropriately selected in accordance with the intended purpose. Examples thereof include fluororesins, such as polyethylene tetrafluoride, polychloro ethylene trifluoride, ethylene tetrafluoride-propylene hexafluoride copolymers, perfluoroalkoxy fluoride resins, polyvinylidene fluoride, ethylene-ethylene tetrafluoride copolymers, ethylene-chloroethylene trifluoride copolymers, polyvinyl fluoride, and the like. These may be used alone or in combination.

### —Metal Oxide-Containing Film—

After the press processing step and before disposition of the second electrode, a metal oxide-containing film may be disposed between the hole-transporting layer and the second electrode.

No particular limitation is imposed on the metal oxide, which may be appropriately selected in accordance with the intended purpose. Examples thereof include molybdenum oxide, tungsten oxide, vanadium oxide, nickel oxide, and the like. These may be used alone or in combination. Of these, molybdenum oxide is preferable. No particular limitation is imposed on a method for disposing the metal oxide-containing film on the hole-transporting layer, which may be appropriately selected in accordance with the intended purpose. Examples thereof include: a method in which a thin film is formed in vacuum, such as vacuum vapor deposition; and a wet film formation method.

The wet film formation method in the case in which the metal oxide-containing film is formed is preferably a method in which a paste is prepared by dispersing powder or sol of the metal oxide, and the paste is coated on the hole-transporting layer.

No particular limitation is imposed on the wet film formation method, which may be appropriately selected in accordance with the intended purpose. Examples thereof include the dip method, the spray method, the wire bar method, the spin coating method, the roller coating method, the blade coating method, the gravure coating method, and the like. As the wet printing method, methods such as relief printing, offset printing, gravure printing, intaglio printing, rubber plate printing, screen printing, or the like may be used.

No particular limitation is imposed on an average thickness of the metal oxide-containing film, which may be appropriately selected in accordance with the intended purpose. However, the average thickness thereof is preferably 0.1 nm (nanometers) or more and 50 nm or less and more preferably 1 nm or more and 10 nm or less.

### <First Substrate>

No particular limitation is imposed on a shape, structure, and size of the first substrate, which may be appropriately selected in accordance with the intended purpose.

No particular limitation is imposed on a material of the first substrate, which may be appropriately selected in accordance with the intended purpose as long as the material has light transmissivity and insulating properties. Examples thereof include substrates, such as glass substrates, plastic films, ceramic substrates, and the like. Of these, in the case in which a firing step for forming the electron-transporting layer is performed as described below, a material having heat resistance to a firing temperature is preferable. More preferably, the first substrate has flexibility.

The substrate may be provided at either one or both of: the outermost part on the first electrode side of the photoelectric conversion element; and the outermost part on the second electrode side of the photoelectric conversion element.

In the following, the substrate provided at the outermost part on the first electrode side will be referred to as the first substrate, and the substrate provided at the outermost part on the second electrode side will be referred to as the second substrate. No particular limitation is imposed on an average thickness of the substrate, which may be appropriately selected in accordance with the intended purpose. For example, the average thickness thereof is 50 micrometers or more and 5 mm or less.

### <First Electrode>

No particular limitation is imposed on a shape and size of the first electrode, which may be appropriately selected in accordance with the intended purpose.

No particular limitation is imposed on a structure of the first electrode, which may be appropriately selected in accordance with the intended purpose. The structure of the first electrode may be a single layer structure or may be a multilayer structure in which layers of a plurality of materials are stacked.

No particular limitation is imposed on a material of the first electrode, which may be appropriately selected in accordance with the intended purpose as long as the material has conductivity. Examples thereof include transparent conductive metal oxides, carbon, metals, and the like.

Examples of the transparent conductive metal oxides include indium-tin oxide (hereinafter referred to as “ITO”), fluorine-doped tin oxide (hereinafter referred to as “FTO”), antimony-doped tin oxide (hereinafter referred to as “ATO”), niobium-doped tin oxide (hereinafter referred to as “NTO”), aluminum-doped zinc oxide (hereinafter referred to as “AZO”), indium-zinc oxide, niobium-titanium oxide, and the like.

Examples of the carbon include carbon black, carbon nanotube, graphene, fullerene, and the like.

Examples of the metals include gold, silver, aluminum, nickel, indium, tantalum, titanium, and the like.

These may be used alone or in combination. Of these, transparent conductive metal oxides having high transparency are preferable, and ITO, FTO, ATO, NTO, and AZO are more preferable.

No particular limitation is imposed on an average thickness of the first electrode, which may be appropriately selected in accordance with the intended purpose. The average thickness of the first electrode is preferably 5 nm or more and 100 micrometers or less and more preferably 50 nm or more and 10 micrometers or less. When a material of the first electrode is carbon or metal, the average thickness of the first electrode is preferably an average thickness sufficient for obtaining light transmissivity.

The first electrode can be formed by publicly known methods, such as the sputtering method, the vapor deposition method, the spray method, and the like.

Moreover, the first electrode is preferably formed on the substrate. It is possible to use a commercially available, first electrode-substrate integrated product in which the first electrode has been formed on the substrate in advance.

Examples of the commercially available, first electrode-substrate integrated product include FTO-coated glass, ITO-coated glass, zinc oxide/aluminum-coated glass, FTO-coated transparent plastic films, ITO-coated transparent plastic films, and the like. Other examples of the commercially available, first electrode-substrate integrated product include: glass substrates provided with a transparent electrode where tin oxide or indium oxide is doped with a cation or an anion having a different atomic valency; and glass substrates provided with a metal electrode having, for example, a mesh- or stripe-shaped structure that transmits light.

These may be used alone, or two or more products may be used in combination as a mixture or stack. Moreover, a metal lead wire may be used in combination in order to decrease an electric resistance value.

In order to produce a photoelectric conversion module that will be described below, the electrode of the commercially available, first electrode-substrate integrated product may be appropriately processed to produce a substrate on which a plurality of first electrodes are formed.

Examples of a material of the metal lead wire includes aluminum, copper, silver, gold, platinum, nickel, and the like.

The metal lead wire can be used in combination by forming the metal lead wire on the substrate through the vapor deposition method, the sputtering method, the pressure bonding method, or the like and disposing a layer of ITO or FTO thereon; or by forming the metal lead wire on ITO or FTO.

### <Electron-Transporting Layer>

The electron-transporting layer means a layer that transports, to the first electrode, electrons generated in the photoelectric conversion layer that will be described below. Therefore, the electron-transporting layer is preferably disposed next to the first electrode.

No particular limitation is imposed on a shape and size of the electron-transporting layer, which may be appropriately selected in accordance with the intended purpose.

The structure of the electron-transporting layer may be a single layer or may be a multilayer in which a plurality of layers are stacked.

The electron-transporting layer includes an electron-transporting material. No particular limitation is imposed on the electron-transporting material, which may be appropriately selected in accordance with the intended purpose. However, the electron-transporting material is preferably a semiconductor material.

No particular limitation is imposed on the semiconductor material, which may be a publicly known material. Examples thereof include simple substance semiconductors, compound semiconductors, and the like.

Examples of the simple substance semiconductors include silicon, germanium, and the like.

Examples of the compound semiconductors include chalcogenides of metals, and the like.

Examples of the chalcogenides of metals include oxides of metals (oxide semiconductors), sulfides of metals, selenides of metals, tellurides of metals, and the like.

Examples of the oxides of metals (oxide semiconductors) include oxides of, for example, titanium, tin, zinc, iron, tungsten, zirconium, hafnium, strontium, indium, cerium, yttrium, lanthanum, vanadium, niobium, tantalum, and the like.

Examples of the sulfides of metals include sulfides of, for example, cadmium, zinc, lead, silver, antimony, bismuth, and the like.

Examples of the selenides of metals include selenides of, for example, cadmium, lead, and the like.

Examples of the tellurides of metals include tellurides of, for example, cadmium, and the like.

Other examples of the compound semiconductor include: phosphides of, for example, zinc, gallium, indium, and cadmium; gallium arsenide; copper-indium-selenide; copper-indium-sulfide; and the like.

Of these, the oxides of metals (oxide semiconductors) are preferable. Especially, it is preferable to include at least one selected from the group consisting of titanium oxide, zinc oxide, tin oxide, and niobium oxide. Inclusion of tin oxide is especially preferable. These may be used alone or in combination. Moreover, no particular limitation is imposed on a crystal type of the semiconductor material, which may be appropriately selected in accordance with the intended purpose. The crystal type thereof may be monocrystalline or polycrystalline, or may be amorphous.

The electron-transporting layer preferably includes, on the electron-transporting material on a surface of the electron-transporting layer on the photoelectric conversion layer side, at least one compound selected from the group consisting of phosphonic acid compounds, boronic acid compounds, sulfonic acid compounds, halogenated silyl compounds, and alkoxysilyl compounds. When the electron-transporting layer includes the above compound on the electron-transporting material on the surface of the electron-transporting layer on the photoelectric conversion layer side, it can be expected that the physical characteristics of the boundary between the electron-transporting layer and the photoelectric conversion layer can be controlled. In other words, when the electron-transporting material is coated with the above compound on the surface of the electron-transporting layer on the photoelectric conversion layer side, it can be expected that a boundary resistance between the electron-transporting layer and the photoelectric conversion layer is decreased, to produce the effect of enabling electrons to be transferred smoothly.

The above compound may be bonded to the electron-transporting material. Examples of the bond include covalent bonds, ionic bonds, and the like.

The compound is at least one compound selected from the group consisting of phosphonic acid compounds, boronic acid compounds, sulfonic acid compounds, halogenated silyl compounds, and alkoxysilyl compounds.

The compound preferably includes a nitrogen atom in terms of compatibility with the photoelectric conversion layer (perovskite layer) that will be described below.

No particular limitation is imposed on the phosphonic acid compounds, which may be appropriately selected in accordance with the intended purpose as long as the phosphonic acid compounds include a phosphonic acid group. Specific examples of the phosphonic acid compounds will be described below.

No particular limitation is imposed on the boronic acid compounds, which may be appropriately selected in accordance with the intended purpose as long as the boronic acid compounds include a boronic acid group. Specific examples of the boronic acid compounds will be described below.

No particular limitation is imposed on the sulfonic acid compounds, which may be appropriately selected in accordance with the intended purpose as long as the sulfonic acid compounds include a sulfonic acid group. Specific examples of the sulfonic acid compounds will be described below.

No particular limitation is imposed on the halogenated silyl compounds, which may be appropriately selected in accordance with the intended purpose as long as the halogenated silyl compounds include a halogenated silyl group. Specific examples of the halogenated silyl compounds will be described below.

No particular limitation is imposed on the alkoxysilyl compounds, which may be appropriately selected in accordance with the intended purpose as long as the alkoxysilyl compounds include an alkoxysilyl group. Specific examples of the alkoxysilyl compounds will be described below.

No particular limitation is imposed on a molecular weight of the above compound, which may be appropriately selected in accordance with the intended purpose. The molecular weight of the compound is, for example, 100 or higher and 500 or lower.

The compound is represented by, for example, formula (X) below.

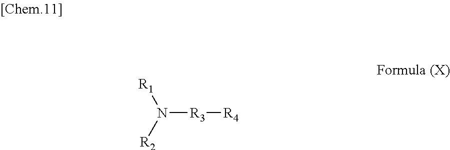

In formula (X), R₁ and R₂, which may be identical to or different from each other, represent a hydrogen atom, an alkyl group, an aryl group, or a heterocycle, R₃ represents a divalent alkylene group, a divalent aryl group, or a divalent heterocycle, R 4 represents a phosphonic acid group, a boronic acid group, a sulfonic acid group, a halogenated silyl group, or an alkoxysilyl group, and R₁ or R₂, R₃, and N may be joined together to form a ring structure.

Examples of the compound include the following compounds and the like.

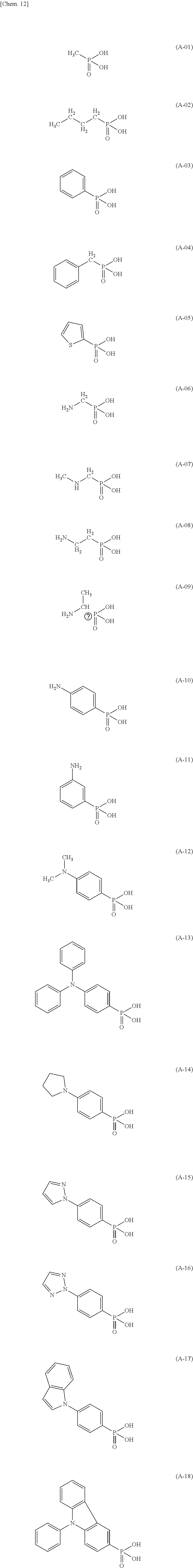

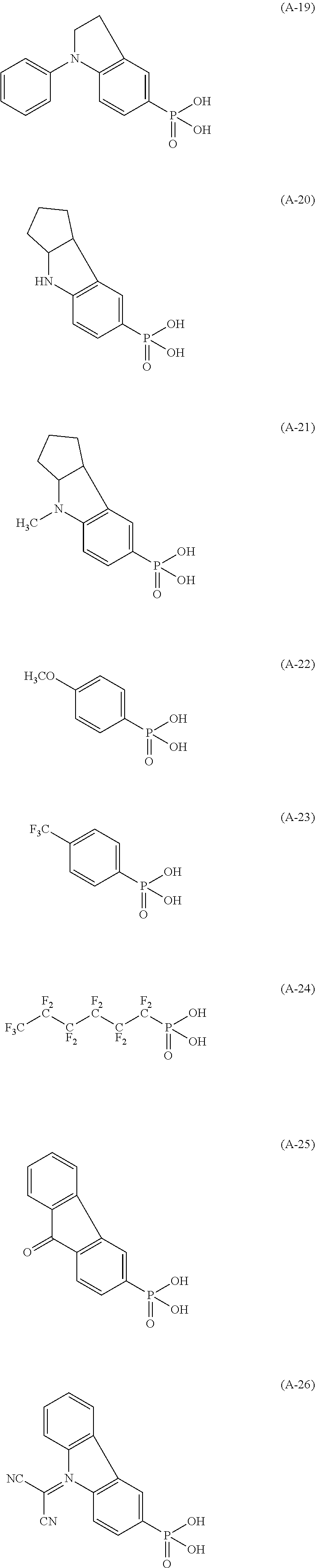

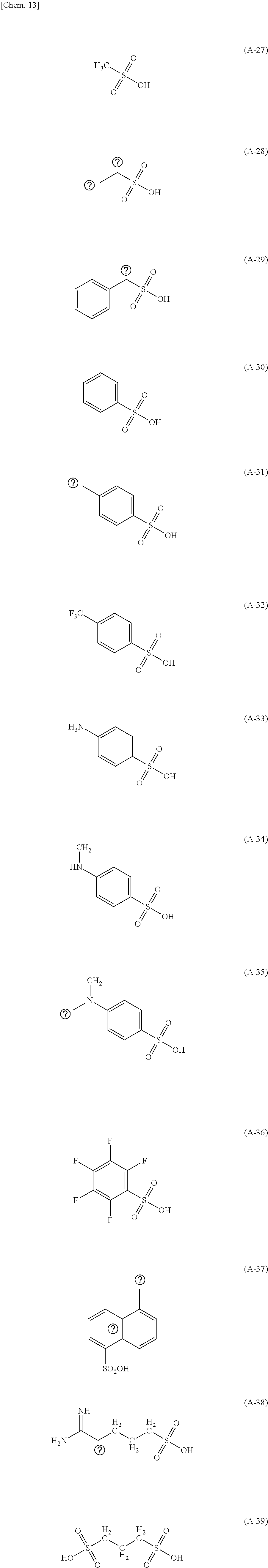

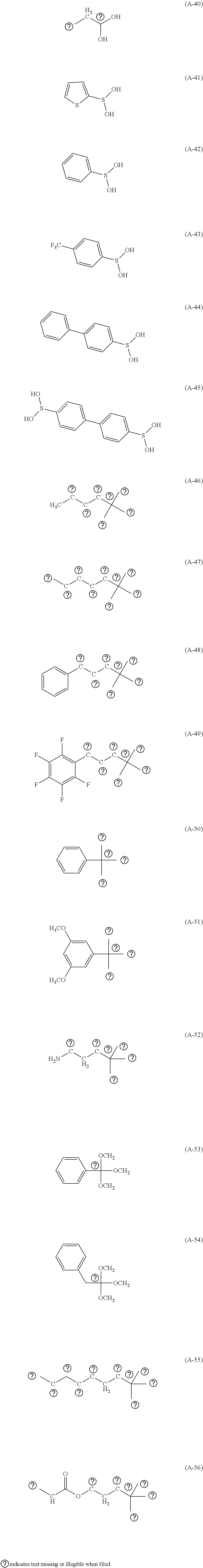

The electron-transporting layer is preferably coated with a compound having a substituent that is reactive with a metal oxide, such as phosphonic acid, sulfonic acid, a halogenated silyl group, or the like, thereby forming a metal oxide surface thereon. Specific examples of the compound that is coated on the surface of the electron-transporting layer include, but are not limited thereto, methylphosphonic acid, phenylphosphonic acid, phenethylphosphonic acid, (1-aminoethyl)phosphonic acid, (2-aminoethyl)phosphonic acid, methanesulfonic acid, benzenesulfonic acid, 2-thienylboronic acid, methyltrichlorosilane, n-hexyltriethoxysilane, and the like.

No particular limitation is imposed on a thickness of the electron-transporting layer, which may be appropriately selected in accordance with the intended purpose. However, the thickness of the electron-transporting layer is preferably 5 nm or more and 1 micrometer or less and more preferably 10 nm or more and 700 nm or less.

The surface of the electron-transporting layer on the photoelectric conversion layer side is preferably as smooth as possible. A roughness factor, which is an indicator representing smoothness, is preferably smaller. However, the roughness factor of the electron-transporting layer on the photoelectric conversion layer side is preferably 20 or less and more preferably 10 or less in terms of a relationship with the average thickness of the electron-transporting layer. No particular limitation is imposed on the lower limit of the roughness factor, which may be appropriately selected in accordance with the intended purpose. The lower limit thereof is, for example, 1 or more. The roughness factor is a ratio of an actual surface area to an apparent surface area, and is also called the Wenzel's roughness factor. The actual surface area can be obtained by measuring, for example, a BET specific surface area. The obtained value can be divided by an apparent surface area to obtain the roughness factor.

No particular limitation is imposed on a method for producing a thin film of the electron-transporting material in the electron-transporting layer, which may be appropriately selected in accordance with the intended purpose. Examples thereof include: a method in which a thin film of the electron-transporting material is formed in vacuum (vacuum film formation method); and a wet film formation method.

Examples of the vacuum film formation method include the sputtering method, the pulse laser deposition method (PLD method), the ion beam sputtering method, the ion assisted deposition method, the ion plating method, the vacuum deposition method, the atomic layer deposition method (ALD method), the chemical vapor deposition method (CVD method), and the like.

Examples of the wet film formation method include a sol-gel method. The sol-gel method is the following method. Specifically, a solution is allowed to undergo chemical reaction, such as hydrolysis or polymerization and/or condensation, to prepare gel. Then, the prepared gel is subjected to a heat treatment to facilitate densification. When the sol-gel method is used, no particular limitation is imposed on a method for coating the sol solution, which may be appropriately selected in accordance with the intended purpose. Examples thereof include the dip method, the spray method, the wire bar method, the spin coating method, the roller coating method, the blade coating method, the gravure coating method, and wet printing methods, such as relief printing, offset printing, gravure printing, intaglio printing, rubber plate printing, screen printing, and the like. A temperature at which the heat treatment is performed after the sol solution is coated is preferably 80 degrees Celsius or higher and more preferably 100 degrees Celsius or higher.

No particular limitation is imposed on a method for providing the compound on the electron-transporting material, which may be appropriately selected in accordance with the intended purpose. Examples thereof include a method in which a solution containing the compound is coated on a thin film of the electron-transporting material, followed by drying.

No particular limitation is imposed on the coating method, which may be appropriately selected in accordance with the intended purpose. Examples thereof include the dip method, the spray method, the wire bar method, the spin coating method, the roller coating method, the blade coating method, the gravure coating method, and the like.

A temperature at which a drying treatment is performed after coating of the solution is preferably 40 degrees Celsius or higher and more preferably 50 degrees Celsius or higher.

### <Photoelectric Conversion Layer>

No particular limitation is imposed on the photoelectric conversion layer, which may be appropriately selected in accordance with the intended purpose as long as the photoelectric conversion layer is a layer that performs photoelectric conversion. Examples of the photoelectric conversion layer include a perovskite layer, a bulk heterojunction layer, and the like.

The photoelectric conversion layer is preferably a perovskite layer having a perovskite structure.

### <<Perovskite Layer>>

The perovskite layer means a layer that contains a perovskite compound and absorbs light to sensitize the electron-transporting layer. Therefore, the perovskite layer is preferably disposed next to the electron-transporting layer.

No particular limitation is imposed on a shape and size of the perovskite layer, which may be appropriately selected in accordance with the intended purpose.

The perovskite compound is a complex substance of an organic compound and an inorganic compound, and is represented by formula (5) below.

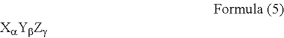

In formula (5), a proportion of α:β:γ is 3:1:1; β and γ are each an integer of more than 1; X represents a halogen atom; Y represents an organic compound containing an amino group, or an alkali metal; and Z represents a metal ion.

No particular limitation is imposed on X in formula (5), which may be appropriately selected in accordance with the intended purpose. Examples thereof include halogen atoms, such as chlorine, bromine, iodine, and the like. These may be used alone or in combination.

No particular limitation is imposed on Y in formula (5), which may be appropriately selected in accordance with the intended purpose. Examples thereof include: amino group-containing organic compounds, such as methyl amine, ethyl amine, n-butylamine, formamidine, and the like; and alkali metals, such as cesium (Cs), rubidium (Rb), potassium (K), and the like. These may be used alone or in combination. The inorganic alkali metal cations may be used in combination, and the organic cations may be used in combination. Of these, amino group-containing organic compounds are preferable.

In the case of the perovskite compound of lead halide and methylammonium, a peak λmax of the optical absorption spectrum is about 350 nm when the halogen ion is Cl, the peak λmax is about 410 nm when the halogen ion is Br, and the peak λmax is about 540 nm when the halogen ion is I. As described above, the peak λmax is shifted to the longer wavelength side, and thus a usable spectrum width (band width) varies.

No particular limitation is imposed on Z in formula (5), which may be appropriately selected in accordance with the intended purpose. Examples thereof include ions of metals, such as lead, indium, antimony, tin, copper, bismuth, and the like. These may be used alone or in combination.

The perovskite layer preferably has a stacked perovskite structure where a layer formed of a metal halide and a layer of arranged organic cation molecules are alternately stacked.

No particular limitation is imposed on a film thickness of the perovskite layer, which may be appropriately selected in accordance with the intended purpose. The film thickness thereof is preferably 50 nm or more and 2 micrometers or less and more preferably 100 nm or more and 600 nm or less.

No particular limitation is imposed on a method for forming the perovskite layer, which may be appropriately selected in accordance with the intended purpose. Examples of the method include a method in which a solution obtained by dissolving or dispersing, for example, a metal halide and halogenated alkylamine or cesium halide is coated, followed by drying.

Moreover, examples of the method for forming the perovskite layer include a twostep precipitation method as described below. Specifically, a solution obtained by dissolving or dispersing a metal halide is coated, followed by drying. Then, the resulting product is immersed in a solution obtained by dissolving halogenated alkylamine, to form the perovskite compound.

Moreover, examples of the method for forming the perovskite layer include a method in which while a solution obtained by dissolving or dispersing, for example, a metal halide and halogenated alkylamine is coated, a poor solvent (solvent having low solubility) for the perovskite compound is added, thereby precipitating crystals. In addition, examples of the method for forming the perovskite layer include a method for vapor-depositing a metal halide in a gas filled with, for example, methylamine.

Of these, it is preferable to use a method in which a poor solvent for the perovskite compound is added while coating a solution obtained by dissolving or dispersing, for example, a metal halide and halogenated alkylamine, thereby precipitating crystals.

No particular limitation is imposed on a method for coating the solution, which may be appropriately selected in accordance with the intended purpose. Examples thereof include the immersion method, the spin coating method, the spray method, the dip method, the roller method, the air knife method, and the like. As the method for coating the solution, a method for performing precipitation in a supercritical fluid using, for example, carbon dioxide may be used.

The perovskite layer may also contain a sensitizing dye.

No particular limitation is imposed on a method for forming the perovskite layer containing the sensitizing dye, which may be appropriately selected in accordance with the intended purpose. Examples thereof include: a method in which the perovskite compound and the sensitizing dye are mixed; and a method in which the perovskite layer is formed, followed by adsorbing the sensitizing dye thereon.

No particular limitation is imposed on the sensitizing dye, which may be appropriately selected in accordance with the intended purpose as long as the sensitizing dye is a compound that is photoexcited by exciting light to be used.

Examples of the sensitizing dye include metal complex compounds, coumarin compounds, polyene compounds, indoline compounds, thiophene compounds, cyanine dyes, merocyanine dyes, 9-arylxanthene compounds, triarylmethane compounds, phthalocyanine compounds, porphyrin compounds, and the like.

Of these, metal complex compounds, indoline compounds, thiophene compounds, and porphyrin compounds are preferable.

### <<Bulk Heterojunction Layer>>

The bulk heterojunction layer contains an electron-donating organic material and an electron-withdrawing organic material.

In the bulk heterojunction layer, an electron-donating organic material (P-type organic semiconductor) and an electron-withdrawing organic material (N-type organic semiconductor) are mixed, thereby forming the bulk heterojunction, which is the nanosized PN junction. As a result, photocharge separation occurring at the junction surface can be used to obtain electric current.

### <<<Electron-Donating Organic Material (P-Type Organic Semiconductor)>>>

Examples of the P-type organic semiconductor include low-molecular-weight compounds and conjugated polymers, such as polythiophene or derivatives thereof, arylamine derivatives, stilbene derivatives, oligothiophene or derivatives thereof, phthalocyanine derivatives, porphyrin or derivatives thereof, polyphenylene vinylene or derivatives thereof, polythienylene vinylene or derivatives thereof, benzodithiophene derivatives, diketo-pyrrolo-pyrrole derivatives, and the like. These may be used alone or in combination.

### <<<Electron-Withdrawing Organic Material (N-Type Organic Semiconductor)>>>

Examples of the electron-withdrawing organic material include imide derivatives, fullerene, fullerene derivatives, and the like. Of these, fullerene derivatives are preferable in terms of charge separation and charge transportation.

No particular limitation is imposed on a method for forming the bulk heterojunction layer, which may be appropriately selected in accordance with the intended purpose. Examples thereof include spin coating, blade coating, slit die coating, screen printing coating, bar coater coating, mold coating, the transfer printing method, the dip drawing method, the inkjet method, the spray method, the vacuum deposition method, and the like. The coating method may be appropriately selected from these coating methods in accordance with the characteristics (e.g., thickness control and orientation control) of the thin film of the organic material to be produced.

An average thickness of the photoelectric conversion layer is preferably 50 nm or more and 400 nm or less and more preferably 60 nm or more and 250 nm or less. When the average thickness thereof is 50 nm or more, insufficient generation of carriers, which is caused due to insufficiency in light absorption by the photoelectric conversion layer, does not occur. When the average thickness thereof is 400 nm or less, the transportation efficiency of carriers generated by light absorption is not further decreased.

### <Film Containing Compound Represented by Formula (6)>

The photoelectric conversion element of the present disclosure may contain a film between the photoelectric conversion layer and the hole-transporting layer, the film containing a compound represented by formula (6) below.

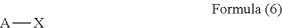

In formula (6), A represents at least one compound selected from the group consisting of amino cations compounds, pyridinium cation compounds, imidazolium cation compounds, and pyrrolidinium cation compounds, represented by formula (7) below or formula (8) below; and X represents a halogen ion.

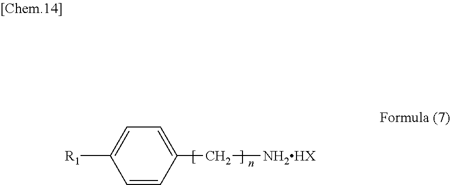

In formula (7), R₁ represents —H, —F, —CF₃, or —OCH₃, n is 1 or 2, and X represents Br or I.

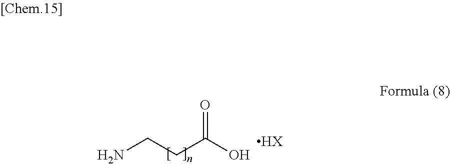

In formula (8), n is an integer of 3 or more and 12 or less, and X represents Br or I.

No particular limitation is imposed on a method for forming the formula (6) compound (organic or inorganic salt)-containing film between the photoelectric conversion layer and the hole-transporting layer, which may be appropriately selected in accordance with the intended purpose. Examples thereof include a method in which a solution containing the formula (6) compound (organic or inorganic salt) is coated on the photoelectric conversion layer, followed by drying, and then the hole-transporting layer is formed thereon. Examples of the solution include aqueous solutions, alcohol solutions, and the like.

No particular limitation is imposed on the coating method of the solution, which may be appropriately selected in accordance with the intended purpose. Examples thereof include the dip method, the spray method, the wire bar method, the spin coating method, the roller coating method, the blade coating method, the gravure coating method, and the like.

As the coating method of the solution, a method for performing precipitation in a supercritical fluid using, for example, carbon dioxide may be used. There is no limitation on the film thickness of this layer. The layer may be formed through adsorption of molecules in the form of a monolayer, or in the form of individual domains without continuity.

No particular limitation is imposed on a temperature at which the drying treatment is performed after coating of the solution, which may be appropriately selected in accordance with the intended purpose.

A film thickness of the formula (6) compound (organic or inorganic salt) is preferably 0.5 nm or more and 100 nm or less and more preferably 1 nm or more and 50 nm or less.

### <Second Substrate>

No particular limitation is imposed on the second substrate, which may be a publicly known substrate. Examples thereof include glass substrates, plastic films, ceramic substrates, and the like. The second substrate may be provided with irregularities in order to increase adhesiveness to a sealing member at a bonded part thereto.

No particular limitation is imposed on a method for forming the irregularities, which may be appropriately selected in accordance with the intended purpose. Examples thereof include the sand blasting method, the water blasting method, a method using abrasive paper, the chemical etching method, the laser processing method, and the like.

A method for increasing adhesiveness between the second substrate and the sealing member may be, for example, a method of removing organic matter on the surface of the second substrate or a method of increasing hydrophilicity of the surface of the second substrate. No particular limitation is imposed on the method of removing the organic matter on the surface of the second substrate, which may be appropriately selected in accordance with the intended purpose. Examples thereof include UV ozone washing, an oxygen plasma treatment, and the like.

### <<Sealing Member>>

The photoelectric conversion element preferably further includes a sealing member configured to shield at least the electron-transporting layer and the hole-transporting layer from the external environment of the photoelectric conversion element.

The sealing member may be a publicly known member as long as the sealing member can reduce entry of an excessive amount of moisture, oxygen, or the like into a sealed part from the external environment, or can prevent mechanical breakage caused through compression from the exterior.

The way of sealing is roughly classified into “frame sealing” and “plane sealing”. In the “frame sealing”, the sealing member is provided at the periphery of a power-generating region formed of the photoelectric conversion layer of the photoelectric conversion element, followed by adhering to the second substrate. In the “plane sealing”, the sealing member is provided over the entirety of the above power-generating region, followed by adhering to the second substrate.

No particular limitation is imposed on a type of the sealing member, which may be appropriately selected in accordance with the intended purpose. Examples thereof include curable resins, low-melting-point glass resins, and the like.

### <Other Members>

No particular limitation is imposed on the other members, which may be appropriately selected in accordance with the intended purpose.

One example of the photoelectric conversion element of the present disclosure will be described below with reference to the drawings. However, the present disclosure should not be construed as being limited thereto. For example, the numbers, positions, shapes, and the like of the following components that are not described in the present embodiment are also encompassed in the scope of the present disclosure.

### (Photoelectric Conversion Module)

The photoelectric conversion module of the present disclosure includes a plurality of the photoelectric conversion elements of the present disclosure that are electrically connected in series or in parallel.

The photoelectric conversion module includes a plurality of the photoelectric conversion elements of the present disclosure on a substrate, and preferably further includes a second substrate different from the above substrate and a sealing member. The photoelectric conversion module includes other members, if necessary.

Examples of the photoelectric conversion module include solar battery modules and the like.

As described above, the photoelectric conversion module includes the photoelectric conversion elements of the present disclosure that are disposed on the substrate. Preferably, in at least two photoelectric conversion elements next to each other, the hole-transporting layers are continuous, and the first electrodes, the electron-transporting layers, and the photoelectric conversion layers are separated by the hole-transporting layers. Because the electron-transporting layers and the photoelectric conversion layers are separated in the photoelectric conversion module, recombination of electrons due to diffusion is reduced. Therefore, the power generation efficiency can be maintained even after exposure to light of a high illuminance for a long period of time.

The photoelectric conversion module of the present disclosure is applicable to power source devices in combination with, for example, a circuit board configured to control generated electric current. Examples of the devices using such a power source device include electronic tabletop calculators, wrist watches, and the like. In addition, the power source device including the photoelectric conversion module of the present disclosure is applicable to, for example, mobile phones, electronic notebooks, electronic paper, and the like. The power source device including the photoelectric conversion module of the present disclosure can be used as an auxiliary power supply configured to prolong a continuous operation time of rechargeable electrical appliances or battery-type electrical appliances, or as a power source that can be used, for example, even in the nighttime by using the power source device in combination with a secondary battery or the like. Moreover, the photoelectric conversion module of the present disclosure can be used in IoT devices or artificial satellites as stand-alone power supplies that do not require replacement of a cell, power source wiring, or the like.

One example of the photoelectric conversion module of the present disclosure will be described below with reference to the drawings. However, the present disclosure should not be construed as being limited thereto. For example, the numbers, positions, shapes, and the like of the following components that are not described in the present embodiment are also encompassed in the scope of the present disclosure.

### Second Embodiment

### —Configuration of Solar Battery Module—

FIG. 1B is a view illustrating one example of a cross-sectional structure of the solar battery module of the present disclosure. As illustrated in FIG. 1B, a solar battery module 100 includes a photoelectric conversion element on a first substrate 1, the photoelectric conversion element including the first electrode 2, the dense electron-transporting layer (dense layer) 3, the porous electron-transporting layer (porous layer) 4, the perovskite layer 5, a formula (6) compound layer 6, the hole-transporting layer 7, and the second electrode 8.

Note that the first electrode 2 and the second electrode 8 have a path that is electrically conducted to an electrode-extracting terminal.

The solar battery module 100 further includes: a second substrate 11 disposed to face the first substrate 1 via the photoelectric conversion element; and a sealing member 10 disposed between the first substrate 1 and the second substrate 11.

In the solar battery module 100, the first electrodes 2, the dense layers 3, the porous layers 4, and the perovskite layers 5 in a photoelectric conversion element “a” including a first electrode 2a and a second electrode 8a and in a photoelectric conversion element “b” including a first electrode 2b and a second electrode 8b are separated by the hole-transporting layer 7 that is a continuous layer extended between the photoelectric conversion element “a” and the photoelectric conversion element “b”.

### Third Embodiment

### —Configuration of Solar Battery Module—

FIG. 1C is a view illustrating one example of a cross-sectional structure of the solar battery module of the present disclosure. As illustrated in FIG. 1C, a solar battery module 101 includes a photoelectric conversion element on the first substrate 1, the photoelectric conversion element including the first electrode 2, the dense electron-transporting layer (dense layer) 3, the perovskite layer 5, the formula (6) compound layer 6, the hole-transporting layer 7, and the second electrode 8.

Note that the first electrode 2 and the second electrode 8 have a path that is electrically conducted to an electrode-extracting terminal.

The solar battery module 101 further includes: the second substrate 11 disposed to face the first substrate 1 via the photoelectric conversion element; and the sealing member 10 disposed between the first substrate 1 and the second substrate 11.

In the solar battery module 101, the first electrodes 2, the dense layers 3, and the perovskite layers 5 in the photoelectric conversion element “a” including the first electrode 2a and the second electrode 8a and in the photoelectric conversion element “b” including the first electrode 2b and the second electrode 8b are separated by the hole-transporting layer 7 that is a continuous layer extended between the photoelectric conversion element “a” and the photoelectric conversion element “b”.

### Fourth Embodiment

### —Configuration of Solar Battery Module—

FIG. 1D is a view illustrating one example of a cross-sectional structure of the solar battery module of the present disclosure. As illustrated in FIG. 1D, a solar battery module 102 includes a photoelectric conversion element on the first substrate 1, the photoelectric conversion element including the first electrode 2, the dense electron-transporting layer (dense layer) 3, the porous electron-transporting layer (porous layer) 4, the perovskite layer 5, the formula (6) compound layer 6, the hole-transporting layer 7, and the second electrode 8.

Note that the first electrode 2 and the second electrode 8 have a path that is electrically conducted to an electrode-extracting terminal.

The solar battery module 102 further includes: the second substrate 11 disposed to face the first substrate 1 via the photoelectric conversion element; and the sealing member 10 disposed between the first substrate 1 and the second substrate 11.

In the solar battery module 102, the first electrodes 2 and the dense layers 3 in the photoelectric conversion element “a” including the first electrode 2a and the second electrode 8a and in the photoelectric conversion element “b” including the first electrode 2b and the second electrode 8b are separated by the porous layer 4, the perovskite layer 5, and the hole-transporting layer 7 that are continuous layers extended between the photoelectric conversion element “a” and the photoelectric conversion element “b”.

### Fifth Embodiment

### —Configuration of Solar Battery Module—

FIG. 1E is a view illustrating one example of a cross-sectional structure of the solar battery module of the present disclosure. As illustrated in FIG. 1E, a solar battery module 103 includes a photoelectric conversion element on the first substrate 1, the photoelectric conversion element including the first electrode 2, the dense electron-transporting layer (dense layer) 3, the porous electron-transporting layer (porous layer) 4, the perovskite layer 5, the formula (6) compound layer 6, the hole-transporting layer 7, and the second electrode 8.

Note that the first electrode 2 and the second electrode 8 have a path that is electrically conducted to an electrode-extracting terminal.

The solar battery module 103 further includes: the second substrate 11 disposed to face the first substrate 1 via the photoelectric conversion element; and the sealing member 10 disposed between the first substrate 1 and the second substrate 11.

In the solar battery module 103, the first electrodes 2, the dense layers 3, and the porous layers 4 in the photoelectric conversion element “a” including the first electrode 2a and the second electrode 8a and in the photoelectric conversion element “b” including the first electrode 2b and the second electrode 8b are separated by the perovskite layer 5 and the hole-transporting layer 7 that are continuous layers extended between the photoelectric conversion element “a” and the photoelectric conversion element “b”.

### Sixth Embodiment

### —Configuration of Solar Battery Module—

FIG. 1F is a view illustrating one example of a cross-sectional structure of the solar battery module of the present disclosure. As illustrated in FIG. 1F, a solar battery module 104 includes a photoelectric conversion element on the first substrate 1, the including the first electrode 2, the dense electron-transporting layer (dense layer) 3, the perovskite layer 5, the formula (6) compound film (layer) 6, the hole-transporting layer 7, and the second electrode 8.

Note that the first electrode 2 and the second electrode 8 have a path that is electrically conducted to an electrode-extracting terminal.

The solar battery module 104 further includes: the second substrate 11 disposed to face the first substrate 1 via the photoelectric conversion element; and the sealing member 10 disposed between the first substrate 1 and the second substrate 11.

In the solar battery module 104, the first electrodes 2 and the dense layers 3 in the photoelectric conversion element “a” including the first electrode 2a and the second electrode 8a and in the photoelectric conversion element “b” including the first electrode 2b and the second electrode 8b are separated by the perovskite layer 5 and the hole-transporting layer 7 that are continuous layers extended between the photoelectric conversion element “a” and the photoelectric conversion element “b”.

The solar battery modules 100 to 104 are sealed by the first substrate 1, the sealing member 10, and the second substrate 11. Therefore, it is possible to control the amount of moisture and the concentration of oxygen in a hollow part between the second electrode 8 and the second substrate 11. By controlling the amount of moisture and the concentration of oxygen in the hollow part of the solar battery modules 100 to 104, power generation performance and durability can be increased. That is, when the solar battery module further includes: the second substrate disposed to face the first substrate via the photoelectric conversion element; and the sealing member disposed between the first substrate and the second substrate and configured to seal the photoelectric conversion element, the amount of moisture and the concentration of oxygen in the hollow part can be controlled, and thus power generation performance and durability can be increased.

No particular limitation is imposed on the concentration of oxygen in the hollow part, which may be appropriately selected in accordance with the intended purpose. The concentration of oxygen in the hollow part is preferably 0% or higher and 21% or lower, more preferably 0.05% or higher and 10% or lower, and further preferably 0.1% or higher and 5% or lower.

In the solar battery modules 100 to 104, the second electrode 8 is not in contact with the second substrate 11, and thus delamination and breakage of the second electrode 8 can be prevented.

The solar battery modules 100 to 104 have a penetration part 9 that electrically connects the photoelectric conversion element “a” and the photoelectric conversion element “b”. In the solar battery modules 100 to 104, the second electrode 8a of the photoelectric conversion element “a” and the first electrode 2b of the photoelectric conversion element “b” are electrically connected via the penetration part 9 that penetrates the hole-transporting layer 7. Thereby, the photoelectric conversion element “a” and the photoelectric conversion element “b” are electrically connected in series. When the plurality of the photoelectric conversion elements are electrically connected in series, the open circuit voltage of the solar battery module can be increased.

The penetration part 9 may penetrate the first electrode 2 and reach the first substrate 1. Alternatively, the penetration part 9 may not reach the first substrate 1 by finishing formation of the penetration part 9 in the first electrode 2. In the case in which the penetration part 9 is shaped into a pore that penetrates the first electrode 2 and reaches the first substrate 1, when the sum of the areas of the openings of the pore is too large relative to the inner surface area of the penetration part 9, the cross-sectional area of the film of the first electrode 2 decreases, and thus a resistance value thereof increases. This can cause reduction in photoelectric conversion efficiency. Therefore, the sum of the areas of the openings of the pore relative to the inner surface area of the penetration part 9 is preferably 5/100 or more and 60/100 or less.

No particular limitation is imposed on a formation method of the penetration part, which may be appropriately selected in accordance with the intended purpose. Examples thereof include the sand blasting method, the water blasting method, the chemical etching method, the laser processing method, a method using abrasive paper, and the like. Of these, the laser processing method is preferable because the pores can be formed without using sand, etching, resist, or the like, and thus can be processed cleanly and reproducibly. Another reason is because the dense layer 3, the porous layer 4, the perovskite layer 5, the formula (6) compound layer 6, the hole-transporting layer 7, the second electrode 8, or any combination thereof can be removed through impact delamination by the laser processing method when forming the penetration part 9. Thereby, there is no need to provide a mask upon stacking, and it is possible to collectively perform the removal of the material forming the photoelectric conversion element and the formation of the penetration part in a simple manner.

The perovskite layer in the photoelectric conversion element “a” and the perovskite layer in the photoelectric conversion element “b” may be continuous or may be separated. When these perovskite layers are separated, a distance therebetween is 1 micrometer or more and 100 micrometers or less and more preferably 5 micrometers or more and 50 micrometers or less. When the distance between the perovskite layer in the photoelectric conversion element “a” and the perovskite layer in the photoelectric conversion element “b” is 1 micrometer or more and 100 micrometers or less, a porous titanium oxide layer and the perovskite layer are separated, and recombination of electrons due to diffusion is reduced. Thus, even after long-term exposure to light of a high illuminance, the photoelectric conversion element can maintain power generation efficiency. That is, regarding at least two photoelectric conversion elements that are next to each other, when the distance between: the electron-transporting layer and the perovskite layer in one photoelectric conversion element; and the electron-transporting layer and the perovskite layer in another photoelectric conversion element is 1 micrometer or more and 100 micrometers or less, even after long-term exposure to light of a high illuminance, the photoelectric conversion element can maintain power generation efficiency.

Note that regarding at least two photoelectric conversion elements that are next to each other, the distance between: the electron-transporting layer and the perovskite layer in one photoelectric conversion element; and the electron-transporting layer and the perovskite layer in another photoelectric conversion element means the shortest distance among the distances between the peripheries (ends) of the electron-transporting layers and the perovskite layers in the respective photoelectric conversion elements.

The solar battery module of the present disclosure is applicable to power source devices by using the solar battery module in combination with, for example, a circuit board configured to control generated electric current. Examples of the devices using such a power source device include electronic tabletop calculators, wrist watches, and the like. In addition, the power source device including the photoelectric conversion element of the present disclosure is applicable to, for example, mobile phones, electronic notebooks, electronic paper, and the like. The power source device including the photoelectric conversion element of the present disclosure can be used as an auxiliary power supply configured to prolong a continuous operation time of rechargeable electrical appliances or battery-type electrical appliances, or as a power source that can be used, for example, in the nighttime by using the power source device in combination with a secondary battery or the like. Moreover, the photoelectric conversion element of the present disclosure can be used in IoT devices or artificial satellites as stand-alone power supplies that do not require replacement of a cell, power source wiring, or the like.

### (Electronic Device)

The electronic device of the present disclosure includes: the photoelectric conversion module of the present disclosure; and a device configured to be driven by electric power generated by the photoelectric conversion module. The electronic device of the present disclosure further includes other devices, if necessary.

### (Power Supply Module)

The power supply module of the present disclosure includes: the photoelectric conversion module of the present disclosure; and a power supply integrated circuit (IC). The power supply module of the present disclosure further includes other devices, if necessary.

Next, a specific embodiment of the electronic device including: the photoelectric conversion module of the present disclosure, the solar battery module of the present disclosure, or both; and a device configured to be driven by electric power obtained through power generation thereof will be described.

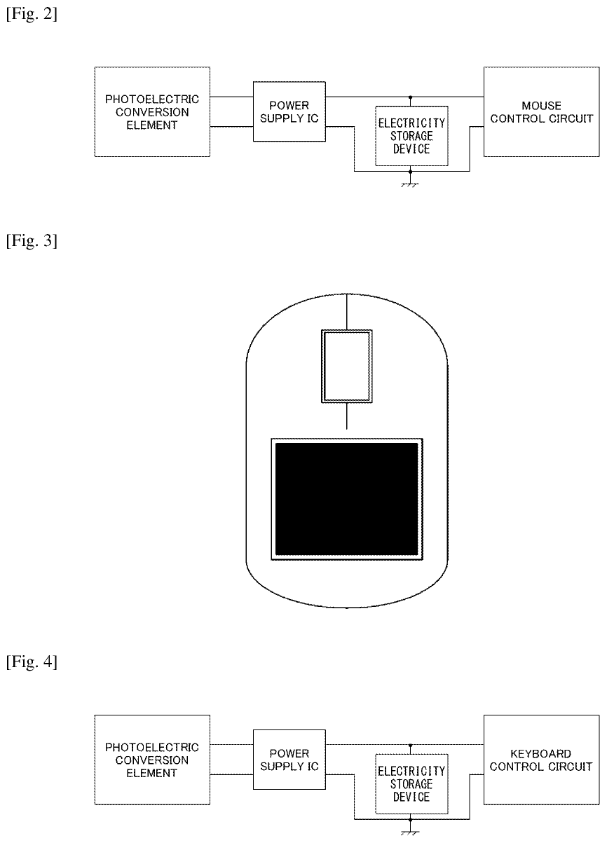

FIG. 2 is a block diagram of a mouse for a personal computer as one example of the electronic device of the present disclosure.

As illustrated in FIG. 2, a photoelectric conversion element of a photoelectric conversion module, a power supply IC, and an electricity storage device are combined and the supplied electric power is allowed to pass to a power supply of a control circuit of the mouse. Thereby, the electricity storage device is charged when the mouse is not used, and the mouse can be driven by the charged electric power. Therefore, a mouse that does not require wiring, replacement of a cell, or the like can be obtained. Because no cell is required, the weight thereof can be reduced, which is advantageous.

FIG. 3 is a schematic external view illustrating one example of the mouse illustrated in FIG. 2.

As illustrated in FIG. 3, the photoelectric conversion element, the power supply IC, and the electricity storage device are mounted in the mouse, but an upper part of the photoelectric conversion element is covered with a transparent housing so that the photoelectric conversion element of the photoelectric conversion module receives light. Moreover, the whole housing of the mouse may be formed with a transparent resin. The arrangement of the photoelectric conversion element is not limited to this. For example, the photoelectric conversion element may be arranged in a position that is irradiated with light even when the mouse is covered with a hand, and such an arrangement may be preferable.

Next, another embodiment of the electronic device including: the photoelectric conversion module of the present disclosure; and the device configured to be driven by electric power obtained through power generation thereof will be described.

FIG. 4 is a block diagram of a keyboard for a personal computer as one example of the electronic device of the present disclosure.

As illustrated in FIG. 4, a photoelectric conversion element of a photoelectric conversion module, a power supply IC, and an electricity storage device are combined, and the supplied electric power is allowed to pass to a power supply of a control circuit of a keyboard. Thereby, the electricity storage device is charged when the keyboard is not used, and the keyboard can be driven by the charged electric power. Therefore, a keyboard that does not require wiring, replacement of a cell, or the like can be obtained. Such a configuration is advantageous because no cell is required and therefore the weight thereof can be reduced.

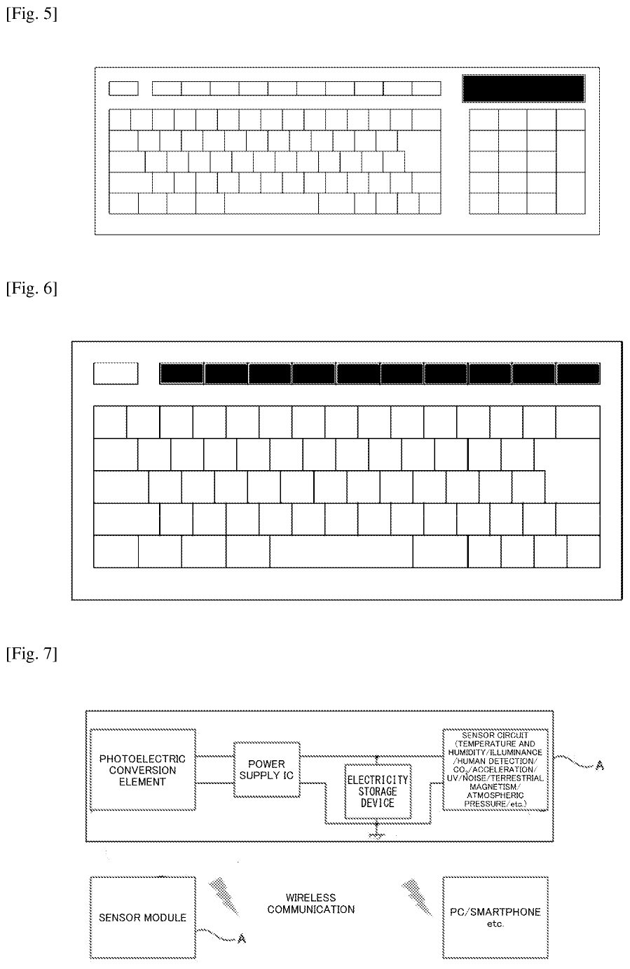

FIG. 5 is a schematic external view illustrating one example of the keyboard illustrated in FIG. 4.

As illustrated in FIG. 5, the photoelectric conversion element of the photoelectric conversion module, the power supply IC, and the electricity storage device are mounted in the keyboard, but an upper part of the photoelectric conversion element is covered with a transparent housing so that the photoelectric conversion element receives light. The whole housing of the keyboard may be formed with a transparent resin. The arrangement of the photoelectric conversion element is not limited to this. In the case of a small keyboard in which a space for inclusion of the photoelectric conversion element is small, a small photoelectric conversion element may be embedded in some of the keys as illustrated in FIG. 6, and such an arrangement is advantageous.

Next, still another embodiment of the electronic device including: the photoelectric conversion module of the present disclosure; and the device configured to be driven by electric power obtained through power generation thereof will be described.

FIG. 7 is a block diagram of a sensor as one example of the electronic device of the present disclosure.

As illustrated in FIG. 7, a photoelectric conversion element of a photoelectric conversion module, a power supply IC, and an electricity storage device are combined, and the supplied electric power is allowed to pass to a power supply of a sensor circuit. Thereby, a sensor module can be formed without requiring connection to an external power supply and without requiring replacement of a cell. A sensing target is, for example, temperature and humidity, illuminance, human detection, CO₂, acceleration, UV, noise, terrestrial magnetism, atmospheric pressure, or the like. Such an electronic device is applicable to various sensors, which is advantageous. As illustrated in FIG. 7, the sensor module is configured to perform sensing of a measurement target on a regular basis and to transmit the read data to a personal computer (PC), a smartphone, or the like through wireless communication.

It is expected that use of sensors will be rapidly increased as the internet of things (IoT) society approaches. Replacing batteries of numerous sensors one by one is laborious and unfeasible. Moreover, a sensor is installed at a position, such as a ceiling and a wall, where a cell is not readily replaceable, and this makes workability inefficient. The fact that electricity can be supplied by the photoelectric conversion element is also significantly advantageous. In addition, the photoelectric conversion module of the present disclosure has advantages that a high output can be obtained even with light of a low illuminance, and a high degree of freedom in installation can be achieved because dependence of light incident angle for the output is small.

Next, yet another embodiment of the electronic device including: the photoelectric conversion module of the present disclosure; and the device configured to be driven by electric power obtained through power generation thereof will be described.

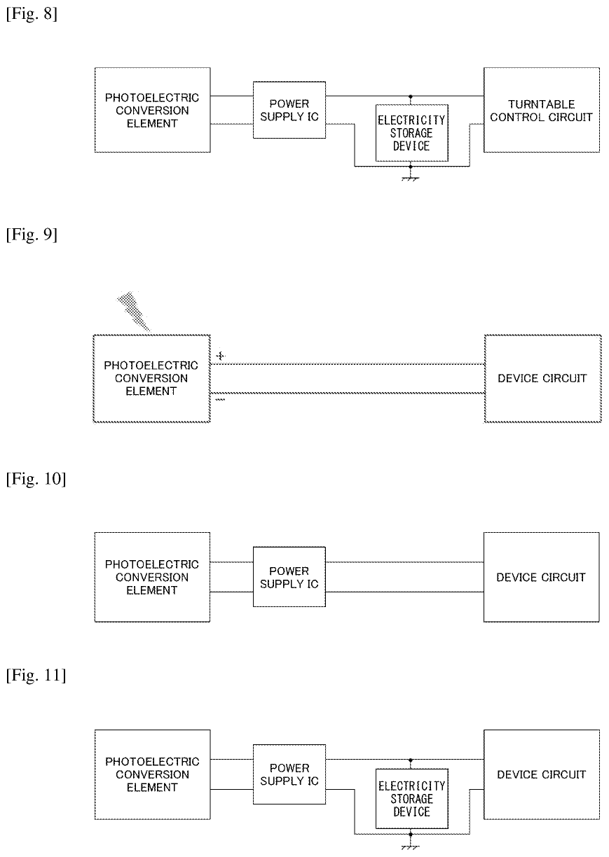

FIG. 8 is a block diagram of a turntable as one example of the electronic device of the present disclosure.

As illustrated in FIG. 8, a photoelectric conversion element, a power supply IC, and an electricity storage device are combined, and the supplied electric power is allowed to pass to a power supply of a turntable control circuit. Thereby, a turntable can be formed without requiring connection to an external power supply and without requiring replacement of a cell.

The turntable is used in, for example, a display case in which merchandise is displayed. Wiring of a power supply degrades appearance of the display, and moreover displayed merchandise needs to be removed at the time of replacing a cell, which is laborious. Use of the photoelectric conversion module of the present disclosure is advantageous because such drawbacks can be overcome.

The electronic device including the photoelectric conversion module of the present disclosure and the device configured to be driven by electric power obtained through power generation thereof, and the power supply module have been described above. However, the described embodiments are only part of applicable embodiments, and use of the photoelectric conversion module of the present disclosure is not limited to the above-described applications.

### <Applications>

The photoelectric conversion module of the present disclosure can function as a stand-alone power supply, and electric power generated through photoelectric conversion can be used to drive a device. Because the photoelectric conversion module of the present disclosure can generate electricity by irradiation with light, it is not necessary to connect the electronic device to a power supply or to replace a cell. Therefore, the electronic device can be driven in a place where there is no power supply facility, the electronic device can be worn or carried, and the electronic device can be driven without replacement of a cell even in a place where a cell is not readily replaceable. Moreover, when a dry cell is used, the electronic device becomes heavier by the weight of the dry cell, or the electronic device becomes larger by the size of the dry cell. Therefore, there may be a disadvantage in installing the electronic device on a wall or ceiling, or carrying the electronic device. However, because the photoelectric conversion module of the present disclosure is lightweight and thin, the photoelectric conversion module can be freely installed, and can be worn and carried, which is advantageous.

As described above, the photoelectric conversion module of the present disclosure can be used as a stand-alone power supply, and can be combined with various electronic devices. For example, the photoelectric conversion module of the present disclosure can be used in combination with a display device (e.g., an electronic tabletop calculator, a wrist watch, a mobile phone, an electronic organizer, electronic paper, or the like), an accessory device of a personal computer (e.g., a mouse, a keyboard, or the like), various sensor devices (e.g., a temperature and humidity sensor, a human detection sensor, or the like), a transmitter (e.g., a beacon, a global positioning system (GPS), or the like), and numerous electronic devices (e.g., an auxiliary lamp, a remote controller, and the like).

Also, by imparting flexibility to the photoelectric conversion element or the photoelectric conversion module, the photoelectric conversion element or the photoelectric conversion module is also applicable to flexible devices.

The photoelectric conversion module of the present disclosure is widely applicable because the photoelectric conversion module can generate electricity, especially from light of a low illuminance, and can generate electricity even indoors and in darker places. Moreover, the photoelectric conversion module is highly safe because the photoelectric conversion module does not involve liquid leakage found in the case of a dry cell, or accidental ingestion found in the case of a button cell. Furthermore, the photoelectric conversion module can be used as an auxiliary power supply for prolonging a continuous operation time of a rechargeable or dry cell-type electrical appliance. As described above, when the photoelectric conversion module of the present disclosure is combined with the device configured to be driven by electric power generated through photoelectric conversion thereof, it is possible to obtain an electronic device that is lightweight and comfortable in use, has a high degree of freedom in installation, does not require replacement of a cell, is excellent in safety, and is advantageous in reducing environmental loads.

FIG. 9 illustrates a basic configuration diagram of an electronic device obtained by combining the photoelectric conversion element of the photoelectric conversion module of the present disclosure with the device configured to be driven by electric power generated through photoelectric conversion thereof. The electronic device can generate electricity when the photoelectric conversion element is irradiated with light, and can extract electric power. A circuit of the device can be driven by the generated electric power.

However, because the output of the photoelectric conversion element of the photoelectric conversion module varies with the illuminance of surrounding light, the electronic device illustrated in FIG. 9 may not be stably driven. In this case, as illustrated in FIG. 10, a power supply IC for a photoelectric conversion element can be included between the photoelectric conversion element and the circuit of the device in order to supply stable voltage to the circuit side. Such an arrangement is advantageous. The photoelectric conversion element of the photoelectric conversion module can generate electricity as long as the photoelectric conversion element is irradiated with light of a sufficient illuminance. However, when light of a sufficient illuminance for generating electricity is not obtained, desired electric power cannot be obtained. This is a disadvantage of the photoelectric conversion element. In this case, as illustrated in FIG. 11, when an electricity storage device, such as a capacitor, is provided between a power supply IC and a device circuit, extra electric power from the photoelectric conversion element can be stored in the electricity storage device. In addition, the electric power stored in the electricity storage device can be supplied to a device circuit, thereby enabling stable operation when the illuminance of light is too low or even when no light is applied to the photoelectric conversion element.

As described above, the electronic device obtained by combining the photoelectric conversion module of the present disclosure with the device circuit can be driven even in an environment with no power supply, does not require replacement of a cell, and can be stably driven, in combination with a power supply IC or an electricity storage device. Therefore, it is possible to make the most of advantages of the photoelectric conversion element.

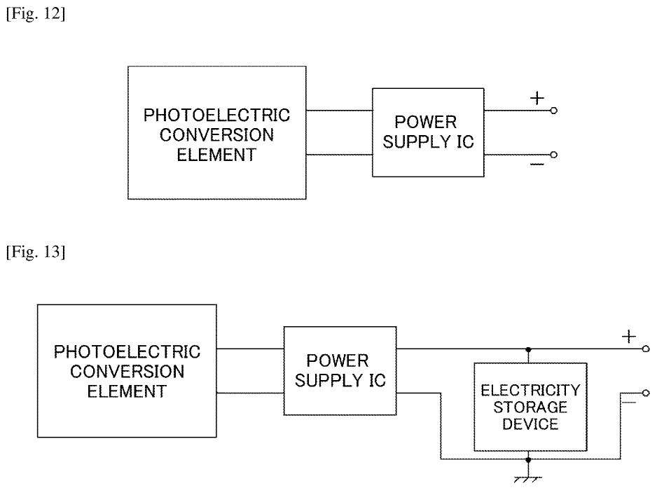

Meanwhile, the photoelectric conversion module of the present disclosure can also be used as a power supply module, which is advantageous. As illustrated in FIG. 12, for example, when the photoelectric conversion module of the present disclosure is connected to a power supply IC for a photoelectric conversion element, it is possible to form a DC power supply module that can supply electric power generated through photoelectric conversion of the photoelectric conversion element of the photoelectric conversion module, to the power supply IC at a predetermined voltage level.

Moreover, as illustrated in FIG. 13, when an electricity storage device is added to the power supply IC, electric power generated by the photoelectric conversion element of the photoelectric conversion module can be stored in the electricity storage device. Therefore, it is possible to form a power supply module that can supply electric power when the illuminance of light is too low or even when no light is applied to the photoelectric conversion element.

The power supply modules of the present disclosure illustrated in FIG. 12 and FIG. 13 can be used as a power supply module without replacement of a cell as in the case of primary cells.

### EXAMPLES

The present disclosure will be described below by way of Examples and Comparative Examples. However, the present disclosure should not be construed as being limited to the Examples described herein.

### Production Example 1

### <Synthesis of Polymer Compound A-14>

A 100-ml four-neck flask was charged with 0.66 g (2.0 mmol) of a dialdehyde compound of structural formula (1) below and 1.02 g (2.0 mmol) of a diphosphonate compound of structural formula (2) below. The flask was purged with nitrogen, followed by addition of 75 ml of tetrahydrofuran. To the resulting solution, 6.75 ml (6.75 mmol) of a 1.0 mol/L tetrahydrofuran solution of potassium t-butoxide was added dropwise, followed by stirring at room temperature for 2 hours. Then, diethyl benzylphosphonate and benzaldehyde were sequentially added thereto, followed by stirring for another 2 hours. About 1 ml of acetic acid was added to complete the reaction, and the reaction solution was washed with water. After the solvent was removed under reduced pressure, the resulting product was reprecipitated using tetrahydrofuran and methanol to perform purification, to obtain 0.95 g of polymer compound A-14.

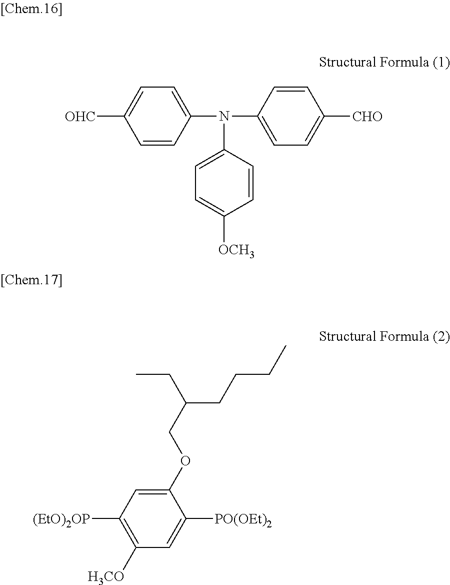

Specifically, polymer compound A-14 was synthesized in accordance with the following reaction scheme.

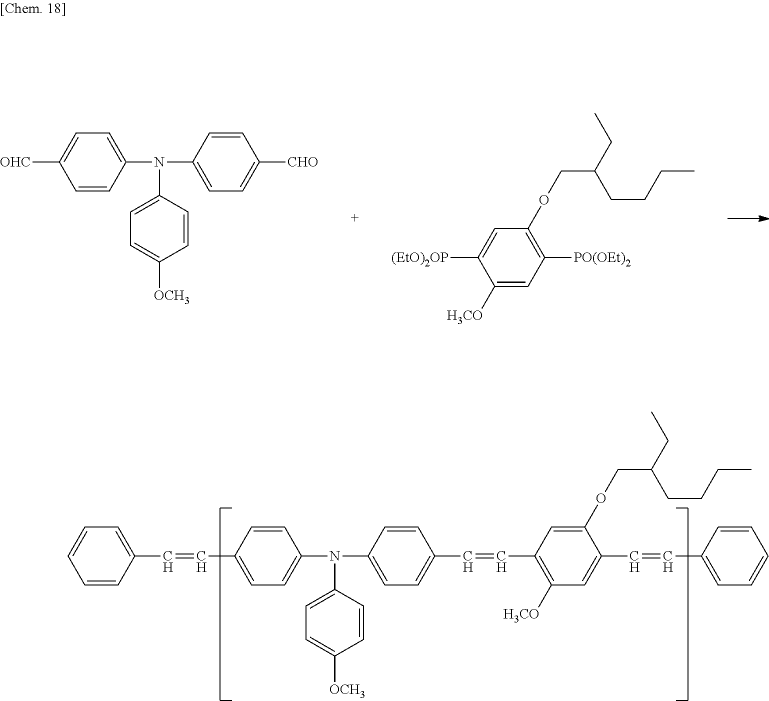

The number average molecular weight and the weight average molecular weight of polymer compound A-14 in terms of polystyrene, which were measured through gel permeation chromatography (GPC), were 8,500 and 20,000, respectively.

The ionization potential of polymer compound A-14 measured using a photoemission yield spectrometer AC-2 (obtained from RIKEN KEIKI Co., Ltd.) was 5.20 eV. The above results were presented in Table 1.

### Production Example 2

### Synthesis of Polymer Compound A-12

Polymer compound A-12 was synthesized in the same manner as in Production Example 1 except that unlike in Production Example 1, the diphosphonate compound was changed to a diphosphonate compound of structural formula (6) below.

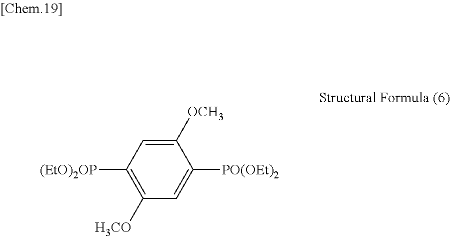

### Production Example 3

### <Synthesis of Polymer Compound A-15>

Polymer compound A-15 was synthesized in the same manner as in Production Example 1 except that unlike in Production Example 1, the dialdehyde compound was changed to a dialdehyde compound of structural formula (7) below and the diphosphonate compound was changed to a diphosphonate compound of structural formula (8) below.

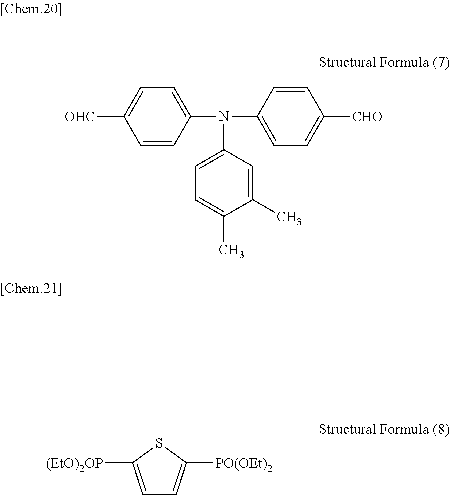

### Production Example 4

### <Synthesis of Polymer Compound A-16>

Polymer compound A-16 was synthesized in the same manner as in Production Example 1 except that unlike in Production Example 1, the dialdehyde compound was changed to a dialdehyde compound of structural formula (7) below and the diphosphonate compound was changed to a diphosphonate compound of structural formula (10) below.

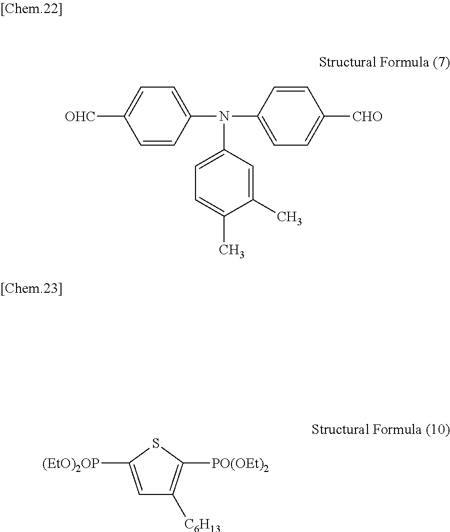

### Production Example 5

### <Synthesis of Polymer Compound A-18>

Polymer compound A-18 was synthesized in the same manner as in Production Example 1 except that unlike in Production Example 1, the dialdehyde compound was changed to a dialdehyde compound of structural formula (11) below and the diphosphonate compound was changed to a diphosphonate compound of structural formula (12) below.

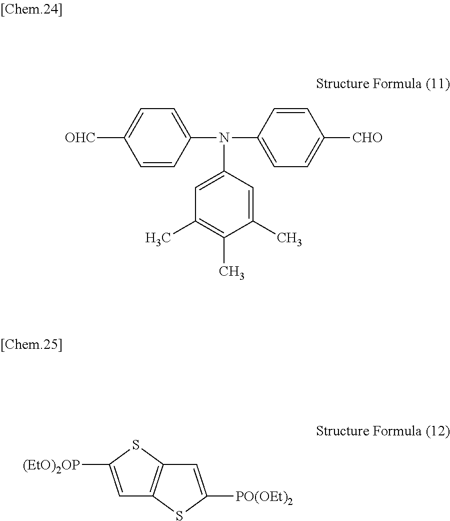

### Production Example 6

### <Synthesis of Polymer Compound A-19>

Polymer compound A-19 was synthesized in the same manner as in Production Example 1 except that unlike in Production Example 1, the dialdehyde compound was changed to a dialdehyde compound of structural formula (13) below and the diphosphonate compound was changed to a diphosphonate compound of structural formula (14) below.

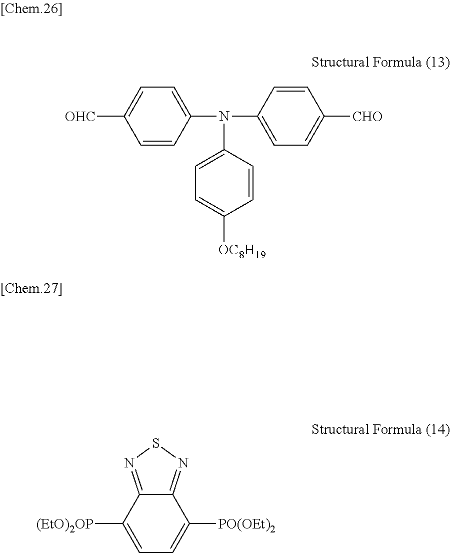

### Production Example 7

<Synthesis of polymer compound A-1>

A 100-ml four-neck flask was charged with 0.66 g (2.0 mmol) of (4,4′-((phenyl)azanediyl)dibenzaldehyde) and 194 mg (8 mmol) of metal magnesium powder. The flask was purged with nitrogen, followed by addition of 10 ml of tetrahydrofuran, 1.44 mL (10.4 mmol) of triethylamine, and 1.54 mL (5.2 mmol) of orthoisopropyl titanate. After the resulting mixture was stirred at 55 degrees Celsius for 48 hours, the reaction was completed by the addition of a saturated aqueous ammonium chloride solution, and the reaction solution was washed with water. After the solvent was removed under reduced pressure, the resulting product was reprecipitated using methylene chloride and methanol to perform purification, to obtain 0.48 g of polymer compound (A-1). The number average molecular weight and the weight average molecular weight of polymer compound (A-1) in terms of polystyrene, which were measured through gel permeation chromatography (GPC), were 4,300 and 5,520, respectively. The ionization potential of polymer compound (A-1) measured using a photoemission yield spectrometer AC-2 (obtained from RIKEN KEIKI Co., Ltd.) was 5.24 eV. All of the ionization potentials described below were values measured by the photoemission yield spectrometer AC-2.

### Example 1

### <Production of Solar Battery Module 1>

A 15% aqueous liquid dispersion of tin oxide (obtained from Alfa Aeser, Product No.: 44592) was diluted with ultrapure water at 1:1, to obtain a dilution of the 15% aqueous liquid dispersion of tin oxide. The obtained dilution was used to form a film on an ITO glass substrate by the spin coating method, followed by drying at 120 degrees Celsius for 30 minutes, thereby forming the electron-transporting layer. Note that an average thickness of the electron-transporting layer was adjusted so as to be from 10 nm through 50 nm.

Then, lead(II) iodide (0.5306 g), lead(II) bromide (0.0736 g), methylamine bromide (0.0224 g), and formamidine hydroiodide (0.1876 g) were added to N,N-dimethylformamide (0.8 ml) and dimethyl sulfoxide (0.2 ml), and were stirred under heating at 60 degrees Celsius, to obtain a solution. Then, the obtained solution was coated on the porous layer by the spin coating method while chlorobenzene (0.3 ml) was added thereto, to form a perovskite film. Subsequently, the perovskite film was dried at 150 degrees Celsius for 30 minutes to form a perovskite layer. An average thickness of the perovskite layer was adjusted so as to be from 200 nm through 350 nm.

Furthermore, a 1 mM solution obtained by dissolving 2-phenylethylammonium bromide as the formula (6) compound in isopropyl alcohol was coated on the formed perovskite layer through spin coating, thereby forming a film containing the formula (6) compound.

Then, 74 mg of polymer compound (A-14) and 7.4 mg of compound (B-1) serving as an oxidant were weighed and dissolved in 3.0 ml of chlorobenzene, to obtain a liquid mixture. The obtained liquid mixture was stirred at room temperature for 4 hours. The stirred liquid mixture was coated by the spin coating method on the stacked product obtained by the above step, thereby forming the hole-transporting layer. Note that an average thickness of the hole-transporting layer (i.e., a part on the perovskite layer) was adjusted so as to be from 50 nm through 120 nm. Moreover, gold was vapor-deposited on the stacked product so as to have an average thickness of 100 nm, thereby forming the second electrode. In this manner, solar battery module 1 was obtained.

### Examples 2 to 20

Solar battery modules were produced in the same manner as in Example 1 except that unlike in Example 1, the composition of the hole-transporting layer was changed to the compositions as shown in Table 1 and Table 2.

### Example 21

A solar battery module was produced in the same manner as in Example 1 except that unlike in Example 1, the composition of the hole-transporting layer was changed to the composition as shown in Table 2 and that aluminum chloride (B-18) was used as an oxidant.

### Comparative Example 1

A solar battery module was produced in the same manner as in Example 1 except that unlike in Example 1, the oxidant was changed to 4-isopropyl-4′-methyldiphenyliodonium tetrakis(pentafluorophenyl)borate (a compound of the following structural formula (15)).

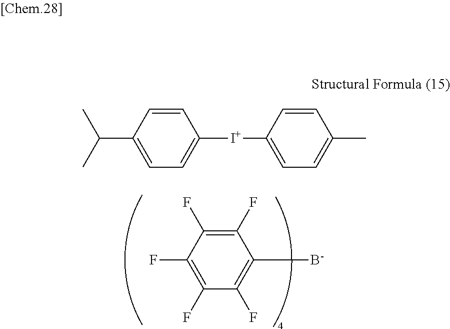

### Comparative Example 2

A solar battery module was produced in the same manner as in Example 1 except that unlike in Example 1, the compound having the constituent unit represented by formula (1) was changed to PTAA.

TABLE 1

| | | | Examples | | | | | | | | | |
|---|---|---|---|---|---|---|---|---|---|---|---|---|
| | | | 1 | 2 | 3 | 4 | 5 | 6 | 7 | 8 | 9 | 10 |
| Polymer | Polymer | A-12 | — | — | — | — | — | — | — | 74 | 74 | 74 |
| | (compound | A-14 | 74 | 74 | 74 | 74 | 74 | 74 | 74 | — | — | — |
| | represented | A-15 | — | — | — | — | — | — | — | — | — | — |
| | by formula (1)) | A-16 | — | — | — | — | — | — | — | — | — | — |
| | | A-18 | — | — | — | — | — | — | — | — | — | — |
| | | A-19 | — | — | — | — | — | — | — | — | — | — |
| | | A-1 | — | — | — | — | — | — | — | — | — | — |
| | Comparative compound | PTAA | — | — | — | — | — | — | — | — | — | — |
| | for polymer | | | | | | | | | | | |
| Oxidant | Oxidant | B-1 | 7.4 | 0.74 | 0.074 | — | — | — | — | 0.74 | — | — |
| | (compound | B-4 | — | — | — | 7.4 | — | — | — | — | 0.074 | — |
| | represented | B-10 | — | — | — | — | 7.4 | — | — | — | — | 0.74 |
| | by formula (2)) | B-13 | — | — | — | — | — | 7.4 | — | — | — | — |
| | | B-17 | — | — | — | — | — | — | 7.4 | — | — | — |
| | | B-18 | — | — | — | — | — | — | — | — | — | — |

| | | | | | | | | | | |
|---|---|---|---|---|---|---|---|---|---|---|
| Compound of structural | — | — | — | — | — | — | — | — | — | — |
| formula (15) | | | | | | | | | | |

TABLE 2

| | | | Examples | | | | | | | | | | |
|---|---|---|---|---|---|---|---|---|---|---|---|---|---|
| | | | 11 | 12 | 13 | 14 | 15 | 16 | 17 | 18 | 19 | 20 | 21 |
| Polymer | Polymer | A-12 | — | — | — | — | — | — | — | — | — | — | — |
| | (compound | A-14 | — | — | — | — | — | — | — | — | — | — | 74 |
| | represented | A-15 | 74 | 74 | 74 | — | — | — | — | — | — | — | — |
| | by formula (1)) | A-16 | — | — | — | 74 | 74 | — | — | — | — | — | — |
| | | A-18 | — | — | — | — | — | 74 | 74 | — | — | — | — |
| | | A-19 | — | — | — | — | — | — | — | 74 | 74 | — | — |
| | | A-1 | — | — | — | — | — | — | — | — | — | 74 | — |
| | Comparative compound | PTAA | — | — | — | — | — | — | — | — | — | — | — |
| | for polymer | | | | | | | | | | | | |
| Oxidant | Oxidant | B-1 | — | — | 7.4 | — | — | 0.074 | — | — | — | 7.4 | — |
| | (compound | B-4 | — | — | — | 7.4 | — | — | — | — | 0.74 | — | — |
| | represented | B-10 | — | — | — | — | 0.74 | — | 0.74 | — | — | — | — |
| | by formula (2)) | B-13 | 0.074 | — | — | — | — | — | — | — | — | — | — |
| | | B-17 | — | 0.74 | — | — | — | — | — | 7.4 | — | — | — |
| | | B-18 | — | — | — | — | — | — | — | — | — | — | 7.4 |

| | | | | | | | | | | | |
|---|---|---|---|---|---|---|---|---|---|---|---|
| Compound of structural | — | — | — | — | — | — | — | — | — | — | — |
| formula (15) | | | | | | | | | | | |

TABLE 3

| | | | Comparative | |
|---|---|---|---|---|
| | | | Examples | |
| | | | 1 | 2 |
| Polymer | Polymer | A-12 | - | - |
| | (compound | A-14 | - | - |
| | represented | A-15 | - | - |
| | by formula (1)) | A-16 | - | - |
| | | A-18 | - | - |
| | | A-19 | - | - |
| | | A-1 | 74 | - |
| | Comparative compound | PTAA | - | 74 |
| | for polymer | | | |
| Oxidant | Oxidant | B-1 | - | 7.4 |
| | (compound | B-4 | - | - |
| | represented | B-10 | - | - |
| | by formula (2)) | 8-13 | - | - |
| | | 8-17 | - | - |
| | | B-18 | - | - |

| | | |
|---|---|---|
| Compound of structural | 7.4 | - |
| formula (15) | | |

### <Evaluation of Gelation>

Regarding the solar battery modules produced in Examples 1 to 21 and Comparative Examples 1 and 2, gelation of the solution (HTL ink) containing the hole-transporting material and the dopant material was evaluated in the following manner. Specifically, 6 hours after mixing of the polymer and the oxidant, the viscosity of the HTL ink was measured at room temperature using a viscometer (Brookfield digital viscometer HBDV2T). Gelation was determined as “Present” when the viscosity was 100,000 mmPa·sec or higher, and gelation was determined as “Absent” when the viscosity was 100 mmPa·sec or lower. The results were presented in Table 4.

TABLE 4

| | Evaluation |
|---|---|
| | results |
| | Gelation |
| Example 1 | Absent |
| Example 2 | Absent |
| Example 3 | Absent |
| Example 4 | Absent |
| Example 5 | Absent |
| Example 6 | Absent |
| Example 7 | Absent |
| Example 8 | Absent |
| Example 9 | Absent |
| Example 10 | Absent |
| Example 11 | Absent |
| Example 12 | Absent |
| Example 13 | Absent |
| Example 14 | Absent |
| Example 15 | Absent |
| Example 16 | Absent |
| Example 17 | Absent |
| Example 18 | Absent |
| Example 19 | Absent |
| Example 20 | Absent |
| Example 21 | Absent |
| Comparative | Present |
| Example 1 | |
| Comparative | Absent |
| Example 2 | |

### <Initial Output>

Regarding the solar battery modules produced in Examples 1 to 21 and Comparative Examples 1 and 2, initial output (η (%)) was evaluated using a solar cell evaluation system (obtained from NF Corporation, Product Name: As-510-PV03) by irradiation with light from a solar simulator (AM 1.5, 100 mW/cm²). The results were presented in Table 5 to Table 7.

### <Retention Rate of Conversion Efficiency: Light Resistance Test>

Regarding the solar battery modules produced in Examples 1 to 21 and Comparative Examples 1 and 2, a retention rate of conversion efficiency (light resistance) ηx/η (%) was determined with characteristics after 500-hour continuous irradiation (AM 1.5, 100 mW/cm²) being a retention rate of conversion efficiency ηx (%). The results were presented in Table 5 to Table 7.

TABLE 5

| | | Examples | | | | | | | | | |
|---|---|---|---|---|---|---|---|---|---|---|---|
| | | 1 | 2 | 3 | 4 | 5 | 6 | 7 | 8 | 9 | 10 |
| Evaluation | Initial output | 17.2 | 17.5 | 15.9 | 17.1 | 17.3 | 16.9 | 17.8 | 18.2 | 15.6 | 16.6 |
| results | Light resistance test | 84 | 85 | 80 | 81 | 80 | 84 | 90 | 91 | 79 | 82 |

TABLE 6

| | | Examples | | | | | | | | | | |
|---|---|---|---|---|---|---|---|---|---|---|---|---|
| | | 11 | 12 | 13 | 14 | 15 | 16 | 17 | 18 | 19 | 20 | 21 |
| Evaluation | Initial output | 14.9 | 17.2 | 17.3 | 18.3 | 17.4 | 15 | 18.2 | 17.1 | 17.2 | 16.9 | 15.4 |
| results | Light resistance test | 78 | 80 | 82 | 81 | 80 | 77 | 93 | 80 | 88 | 69 | 72 |

TABLE 7

| | | Comparative | |
|---|---|---|---|
| | | Examples | |
| | | 1 | 2 |
| Evaluation | Initial output | 5.3 | 15.2 |
| results | Light resistance test | 54 | 53 |

As is clear from Examples 1 to 21 and Comparative Examples 1 and 2, inclusion of the polymer compound having the constituent unit represented by formula (1) and the compound represented by formula (2) can provide the hole-transporting layer-forming liquid composition that is free of gelation and is stable. It is also clear that the hole-transporting layer formed using the hole-transporting layer-forming liquid composition contains the polymer compound having the constituent unit represented by formula (1) and the compound represented by formula (2), excellent initial output is obtained, and even after long-term exposure to light, excellent power generation efficiency can be maintained.

Aspects of the present disclosure are, for example, as follows.
<1> A photoelectric conversion element, including:
a hole-transporting layer, wherein
the hole-transporting layer contains
a polymer compound having a constituent unit represented by formula (1) below; and
a compound represented by formula (2) below:

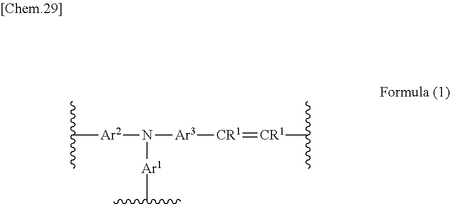

in formula (1), Ar¹, Ar², and Ar³ each independently represent a divalent group of a substituted or unsubstituted, monocyclic, non-condensed polycyclic, or condensed polycyclic aromatic hydrocarbon group, and R¹ represents hydrogen, an alkyl group, or an aryl group;

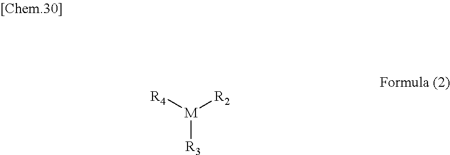

in formula (2), M represents boron, aluminum, phosphorus, or antimony, and R₂, R₃, and R₄ represent hydrogen, a halogen, an alkyl group, an alkoxy group, an aryl group, a heteroaryl group, an ether bond-containing group, or an ester bond-containing group.
<2> The photoelectric conversion element according to <1>, wherein the polymer compound having the constituent unit represented by formula (1) is a compound represented by formula (3):

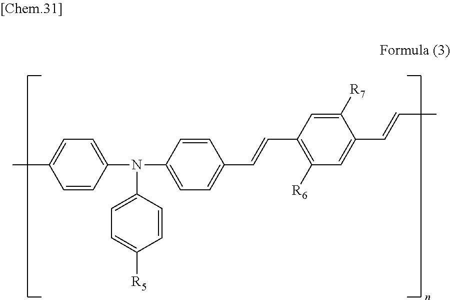

in formula (3), R₅ represents a methyl group or a methoxy group, R₆ and R₇ represent an alkoxy group, and n is an integer of 2 or more.
<3> The photoelectric conversion element according to <1> or <2>, wherein the compound represented by formula (2) is a compound represented by formula (4):

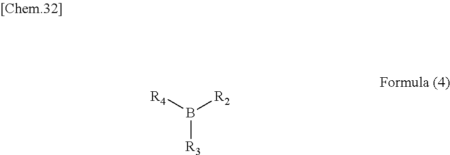

in formula (4), R₂, R₃, and R₄ represent hydrogen, a halogen, an alkyl group, an alkoxy group, an aryl group, a heteroaryl group, an ether bond-containing group, or an ester bond-containing group.
<4> The photoelectric conversion element according to any one of <1> to <3>, wherein at least two selected from the group consisting of R₂, R₃, and R₄ in formula (2) are an aryl group substituted with fluorine.
<5> The photoelectric conversion element according to any one of <1> to <4>, wherein a mass ratio (A/B) is 2 or more and 100 or less, where A denotes a content of the polymer compound having the constituent unit represented by formula (1) and B denotes a content of the compound represented by formula (2).
<6> The photoelectric conversion element according to any one of <1> to <5>, further including a photoelectric conversion layer, wherein the photoelectric conversion layer contains a compound represented by formula (5):

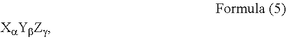

in formula (5), a proportion of α:β:γ is 3:1:1; β and γ are each an integer of more than 1; X represents a halogen atom; Y represents an organic compound containing an amino group, or an alkali metal; and Z represents a metal ion.
<7> The photoelectric conversion element according to <6>, wherein Y is at least one selected from the group consisting of cesium, rubidium, and potassium, and Z is antimony.
<8> The photoelectric conversion element according to any one of <1> to <7>, further including:
an electron-transporting layer, wherein the electron-transporting layer contains tin oxide.
<9> A photoelectric conversion module, including:
the photoelectric conversion element according to any one of <1> to <8>, which is connected to the photoelectric conversion module.
<10> An electronic device, including:
the photoelectric conversion module according to <9>; and a device configured to be driven by electric power generated by the photoelectric conversion module.
<11> A power supply module, including:
the photoelectric conversion module according to <9>; and a power supply integrated circuit (IC).
<12> A liquid composition, including:
a polymer compound having a constituent unit represented by formula (1) below; and
a compound represented by formula (2):

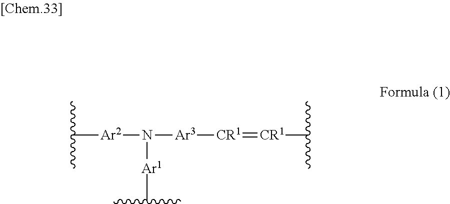

in formula (1), Ar¹, Ar², and Ar³ each independently represent a divalent group of a substituted or unsubstituted, monocyclic, non-condensed polycyclic, or condensed polycyclic aromatic hydrocarbon group, and R¹ represents hydrogen, an alkyl group, or an aryl group;

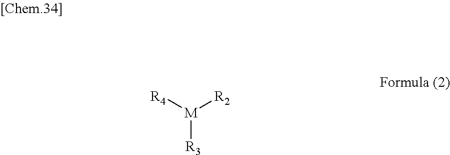

in formula (2), M represents boron, aluminum, phosphorus, or antimony, and R₂, R₃, and R₄ represent hydrogen, a halogen, an alkyl group, an alkoxy group, an aryl group, a heteroaryl group, an ether bond-containing group, or an ester bond-containing group.

The photoelectric conversion element according to any one of <1> to <8>, the photoelectric conversion module according to <9>, the electronic device according to <10>, the power supply module according to <11>, and the liquid composition according to <12> can solve the existing problems and achieve the object of the present disclosure.

This application is based upon and claims priority to Japanese Patent Application No. 2023-044628, filed on Mar. 20, 2023, the entire contents of which are incorporated herein by reference.

### REFERENCE SIGNS LIST

1 first substrate
2, 2a, 2b first electrode
3 dense electron-transporting layer (dense layer)
4 porous electron-transporting layer (porous layer)
5 perovskite layer
6 formula (6) compound-containing layer
7 hole-transporting layer
8, 8a, 8b second electrode
9 penetration part
10 sealing member
11 second substrate
50 solar battery cell
100, 101, 102, 103, 104 solar battery module

1. A photoelectric conversion element, comprising:
a hole-transporting layer, wherein
the hole-transporting layer contains
a polymer compound having a constituent unit represented by formula (1) below, and
a compound represented by formula (2) below: 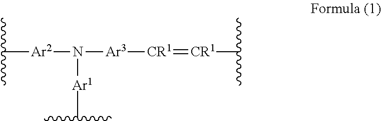
in formula (1), Ar¹, Ar², and Ar³ each independently represent a divalent group of a substituted or unsubstituted, monocyclic, non-condensed polycyclic, or condensed polycyclic aromatic hydrocarbon group, and R¹ represents hydrogen, an alkyl group, or an aryl group; 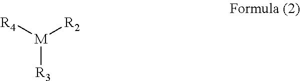
in formula (2), M represents boron, aluminum, phosphorus, or antimony, and R₂, R₃, and R₄ represent hydrogen, a halogen, an alkyl group, an alkoxy group, an aryl group, a heteroaryl group, an ether bond-containing group, or an ester bond-containing group.

2. The photoelectric conversion element according to claim 1,
wherein
the polymer compound having the constituent unit represented by formula (1) is a compound represented by formula (3): 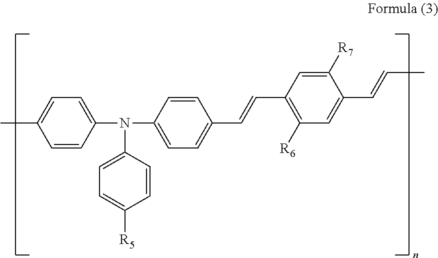
in formula (3), R₅ represents a methyl group or a methoxy group, R₆ and R₇ represent an alkoxy group, and n is an integer of 2 or more.

3. The photoelectric conversion element according to claim 1, wherein
the compound represented by formula (2) is a compound represented by formula (4): 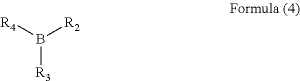
in formula (4), R₂, R₃, and R₄ represent hydrogen, a halogen, an alkyl group, an alkoxy group, an aryl group, a heteroaryl group, an ether bond-containing group, or an ester bond-containing group.

4. The photoelectric conversion element according to claim 1, wherein
at least two selected from the group consisting of R₂, R₃, and R₄ in formula (2) are an aryl group substituted with fluorine.

5. The photoelectric conversion element according to claim 1, wherein
a mass ratio (A/B) is 2 or more and 100 or less, where A denotes a content of the polymer compound having the constituent unit represented by formula (1) and B denotes a content of the compound represented by formula (2).

6. The photoelectric conversion element according to claim 1, further comprising:
a photoelectric conversion layer, wherein
the photoelectric conversion layer contains a compound represented by formula (5): 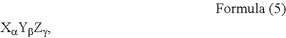
in formula (5), a proportion of α:β:γ is 3:1:1; β and γ are each an integer of more than 1;
X represents a halogen atom; Y represents an organic compound containing an amino group, or an alkali metal; and Z represents a metal ion.

7. The photoelectric conversion element according to claim 6, wherein
Y is at least one selected from the group consisting of cesium, rubidium, and potassium, and Z is antimony.

8. The photoelectric conversion element according to claim 1, further comprising:
an electron-transporting layer, wherein
the electron-transporting layer contains tin oxide.

9. A photoelectric conversion module, comprising:
the photoelectric conversion element according to claim 1, which is connected to the photoelectric conversion module.

10. An electronic device, comprising:
the photoelectric conversion module according to claim 9; and
a device configured to be driven by electric power generated by the photoelectric conversion module.

11. A power supply module, comprising:
the photoelectric conversion module according to claim 9; and
a power supply integrated circuit (IC).

12. A liquid composition, comprising:
a polymer compound having a constituent unit represented by formula (1) below; and
a compound represented by formula (2): 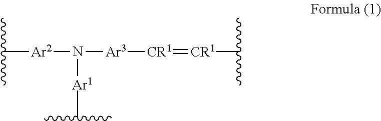
in formula (1), Ar¹, Ar², and Ar³ each independently represent a divalent group of a substituted or unsubstituted, monocyclic, non-condensed polycyclic, or condensed polycyclic aromatic hydrocarbon group, and R¹ represents hydrogen, an alkyl group, or an aryl group; 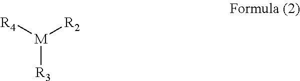
in formula (2), M represents boron, aluminum, phosphorus, or antimony, and R₂, R₃, and R₄ represent hydrogen, a halogen, an alkyl group, an alkoxy group, an aryl group, a heteroaryl group, an ether bond-containing group, or an ester bond-containing group.
